(19) United States
(12) Patent Application Publication
(10) Pub. No.: US 2025/0331238 A1
(43) Pub. Date: Oct. 23, 2025

(54) SEMICONDUCTOR DEVICE

(71) Applicant: Samsung Electronics Co., Ltd., Suwon-si (KR)

(72) Inventors: Jaeho JEON, Suwon-si (KR); DONGHOON HWANG, Suwon-si (KR); Seongkwang KIM, Suwon-si (KR); Jisoo KIM, Suwon-si (KR); DONG-HWAN HAN, Suwon-si (KR)

(21) Appl. No.: 18/982,503

(22) Filed: Dec. 16, 2024

(30) Foreign Application Priority Data
Apr. 23, 2024 (KR) 10-2024-0054060

(51) Int. Cl. H10D 30/67; H10D 62/13; H10D 84/03; H10D 84/85; H10D 88/00

(52) U.S. Cl. CPC H10D 30/6757; H10D 30/6735; H10D 62/151; H10D 84/038; H10D 84/85; H10D 88/00

(57) ABSTRACT

A semiconductor device may include a substrate, a lower channel pattern, a lower source/drain pattern, an upper channel pattern, an upper source/drain pattern, and a gapfill insulating pattern. A side surface of the gapfill insulating pattern faces a side surface of the lower source/drain pattern and a side surface of the upper source/drain pattern. The gapfill insulating pattern has a recessed top surface, and a distance between the recessed top surface of the gapfill insulating pattern and a lower surface of the substrate in a first direction is greater than a distance between an uppermost portion of the lower source/drain pattern and the lower surface of the substrate in the first direction and is less than a distance between an uppermost portion of the upper source/drain pattern and the lower surface of the substrate in the first direction.

### CROSS-REFERENCE TO RELATED APPLICATIONS

This U.S. non-provisional patent application claims priority under 35 U.S.C. § 119 to Korean Patent Application No. 10-2024-0054060, filed on Apr. 23, 2024, in the Korean Intellectual Property Office, the entire contents of which are hereby incorporated by reference.

### TECHNICAL FIELD

The present disclosure relates to a semiconductor device, and more specifically, to a semiconductor device including a field effect transistor and a method of fabricating the same.

### BACKGROUND OF THE INVENTION

A semiconductor device may include an integrated circuit including metal-oxide-semiconductor field-effect transistors (MOSFETs). To meet an increasing demand for a semiconductor device with a small pattern size and a reduced design rule, the sizes of the MOSFETs are being reduced. The reduced sizes of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY OF THE INVENTION

An embodiment of the inventive concept provides a semiconductor device with an increased integration density and improved electrical characteristics.

An embodiment of the inventive concept provides a method of fabricating a semiconductor device with an increased integration density and improved electrical characteristics.

According to an embodiment of the inventive concept, a semiconductor device may include a lower active region on a substrate, the lower active region including a lower channel pattern and a lower source/drain pattern electrically connected to the lower channel pattern, an upper active region on the lower active region, the upper active region including an upper channel pattern and an upper source/drain pattern electrically connected to the upper channel pattern, and a gapfill insulating pattern. A side surface of the gapfill insulating pattern faces a side surface of the lower source/drain pattern and a side surface of the upper source/drain pattern. The gapfill insulating pattern has a recessed top surface, where a distance between the recessed top surface of the gapfill insulating pattern and a lower surface of the substrate in a first direction that is perpendicular to the lower surface of the substrate is greater than a distance between an uppermost portion of the lower source/drain pattern and the lower surface of the substrate in the first direction and is less than a distance between an uppermost portion of the upper source/drain pattern and the lower surface of the substrate in the first direction.

According to an embodiment of the inventive concept, a semiconductor device may include a lower active region on a substrate, the lower active region including a lower channel pattern and lower source/drain patterns electrically connected to the lower channel pattern, an upper active region on the lower active region, the upper active region including an upper channel pattern and upper source/drain patterns electrically connected to the upper channel pattern, a gate electrode on the lower channel patterns and the upper channel patterns, the gate electrode including a lower gate electrode on the lower channel pattern, an upper gate electrode on the upper channel pattern, and an outer electrode that is an uppermost portion of the upper gate electrode, a gapfill insulating pattern, a side surface of the gapfill insulating pattern facing side surfaces of the lower source/drain patterns and side surfaces of the upper source/drain patterns, a first spacer on a side surface of the outer electrode and the side surface of the gapfill insulating pattern, and a second spacer on a side surface of the first spacer. The gapfill insulating pattern has a top surface that is recessed toward the substrate in in a first direction that is perpendicular to a lower surface of the substrate, and where the top surface of the gapfill insulating pattern is between the upper source/drain patterns in a second direction that is parallel to the lower surface of the substrate.

According to an embodiment of the inventive concept, a semiconductor device may include a lower active region on a substrate, the lower active region including a lower channel pattern and a lower source/drain pattern electrically connected to the lower channel pattern, an upper active region on the lower active region, the upper active region including an upper channel pattern and an upper source/drain pattern electrically connected to the upper channel pattern, a gate electrode on the lower channel pattern and the upper channel pattern, the gate electrode including a lower gate electrode on the lower channel pattern, an upper gate electrode on the upper channel pattern, and an outer electrode that is an uppermost portion of the upper gate electrode, a gapfill insulating pattern, a side surface of the gapfill insulating pattern facing a side surface of the lower source/drain pattern and a side surface of the upper source/drain pattern, a first interlayer insulating layer on the lower source/drain pattern, a second interlayer insulating layer on the upper source/drain pattern, a lower active contact electrically connected to the lower source/drain pattern, an upper active contact electrically connected to the upper source/drain pattern, a first spacer on a side surface of the outer electrode and a side surface of the gapfill insulating pattern, and a second spacer on a side surface of the first spacer. The gapfill insulating pattern has a recessed top surface, and a distance between the recessed top surface of the gapfill insulating pattern and a lower surface of the substrate in a first direction that is perpendicular to a lower surface of the substrate is greater than a distance between an uppermost portion of the lower source/drain pattern and the lower surface of the substrate in the first direction and is less than a distance between an uppermost portion of the upper source/drain pattern and the lower surface of the substrate in the first direction.

### BRIEF DESCRIPTION OF THE DRAWINGS

FIG. 1 is a conceptual diagram illustrating a logic cell of a semiconductor device according to a comparative example.

FIG. 2 is a conceptual diagram illustrating a logic cell of a semiconductor device according to an embodiment of the inventive concept.

FIG. 3 is a plan view illustrating a three-dimensional semiconductor device according to an embodiment of the inventive concept.

FIGS. 4A, 4B, 4C, and 4D are sectional views, which are respectively taken along lines A-A′, B-B′, C-C′, and D-D′ of FIG. 3.

FIGS. 5A, 5B, 6A, 6B, 6C, 7A, 7B, 7C, 8A, 8B, 8C, 9A, 9B, 9C, 10A, 10B, 11A, 11B, 11C, 12A, 12B, 12C, 12D, 13A, 13B, 13C, 13D, 14A, 14B, 14C, and 14D are sectional views illustrating a method of fabricating a semiconductor device according to an embodiment of the inventive concept.

FIGS. 15A and 15B are sectional views illustrating a semiconductor device according to an embodiment of the inventive concept.

FIGS. 16A, 16B, and 16C are plan and sectional views illustrating a semiconductor device according to an embodiment of the inventive concept.

FIG. 17 and FIGS. 18A, 18B, and 18C are plan and sectional views illustrating a semiconductor device according to an embodiment of the inventive concept.

FIGS. 19A and 19B are plan and sectional views illustrating a semiconductor device according to an embodiment of the inventive concept.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

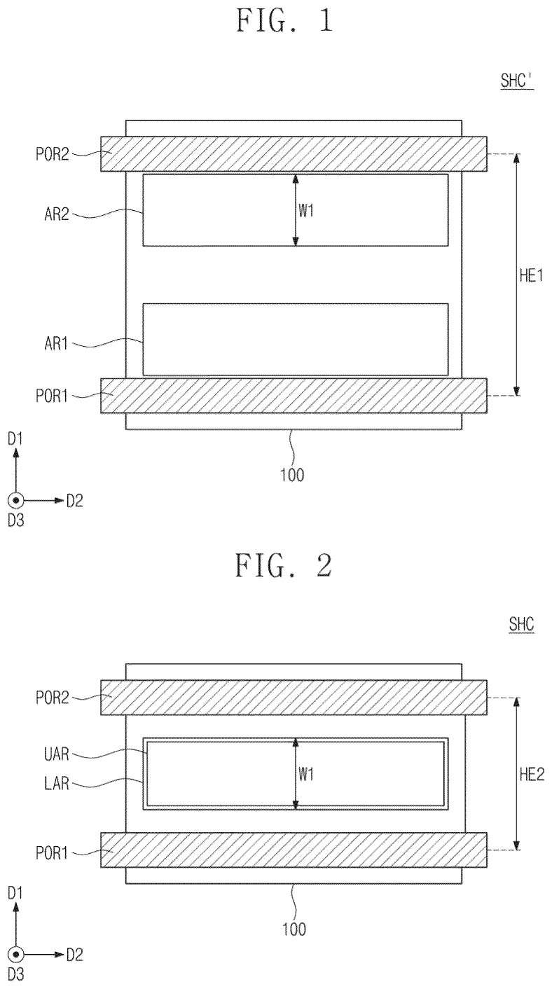

FIG. 1 is a conceptual diagram illustrating a logic cell of a semiconductor device according to a comparative example. FIG. 1 illustrates a logic cell of a two-dimensional device according to the comparative example.

Referring to FIG. 1, a single height cell SHC′ may be provided. In detail, a first power line POR1 and a second power line POR2 may be provided on a substrate 100. A drain voltage (i.e., a power voltage) may be applied to one of the first and second power lines POR1 and POR2. A source voltage (i.e., a ground voltage) may be applied to the other of the first and second power lines POR1 and POR2. In an embodiment, the source voltage may be applied to the first power line POR1, and the drain voltage may be applied to the second power line POR2.

The single height cell SHC′ may be defined between the first power line POR1 and the second power line POR2. The single height cell SHC′ may include a first active region AR1 and a second active region AR2. One of the first and second active regions AR1 and AR2 may be a PMOSFET region, and the other of the first and second active regions AR1 and AR2 may be an NMOSFET region. For example, the first active region AR1 may be an NMOSFET region, and the second active region AR2 may be a PMOSFET region. That is, the single height cell SHC′ may include a CMOS structure that is provided between the first and second power lines POR1 and POR2.

The semiconductor device according to the comparative example may be a two-dimensional device, in which the transistors of the front-end-of-line (FEOL) layer are two-dimensionally arranged. For example, an NMOSFET of the first active region AR1 may be spaced apart from a PMOSFET of the second active region AR2 in a first direction D1.

Each of the first and second active regions AR1 and AR2 may have a first width W1 in the first direction D1. In the comparative example, a length of the single height cell SHC′ in the first direction D1 may be defined as a first height HE1. The first height HE1 may be substantially equal to a distance (e.g., pitch) between the first and second power lines POR1 and POR2.

The single height cell SHC′ may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

In the comparative example, since the single height cell SHC′ includes a two-dimensional device, the first and second active regions AR1 and AR2 may not be overlapped by each other and may be spaced apart from each other in the first direction D1. Thus, the first height HE1 of the single height cell SHC′ may be defined to span both the lower and upper active regions LAR and UAR, which are spaced apart from each other in the first direction D1. As a result, the first height HE1 of the single height cell SHC′ according to the comparative example may be increased to have a relatively large value. That is, the single height cell SHC′ in the comparative example may have a relatively large area.

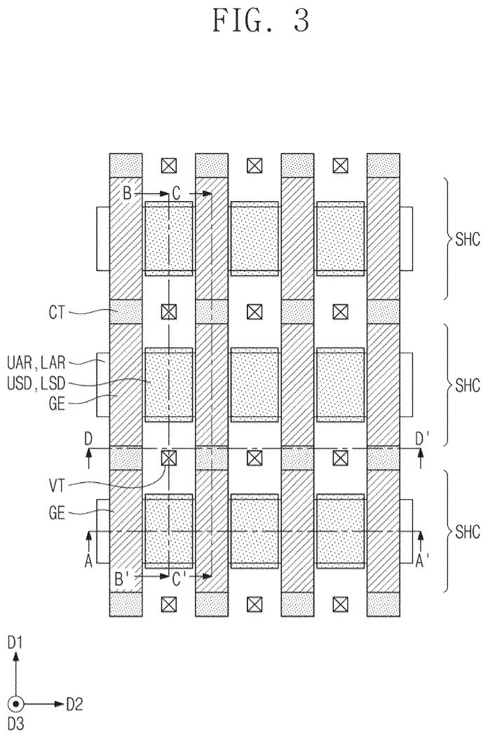

FIG. 2 is a conceptual diagram illustrating a logic cell of a semiconductor device according to an embodiment of the inventive concept. FIG. 2 illustrates a logic cell of a three-dimensional device according to an embodiment of the inventive concept.

Referring to FIG. 2, a single height cell SHC, which includes a three-dimensional device with stacked transistors, may be provided. In detail, the first power line POR1 and the second power line POR2 may be provided on the substrate 100. The single height cell SHC may be defined between the first power line POR1 and the second power line POR2.

The single height cell SHC may include a lower active region LAR and an upper active region UAR. One of the lower and upper active regions LAR and UAR may be a PMOSFET region, and the other of the lower and upper active regions LAR and UAR may be an NMOSFET region.

In the present embodiment, the semiconductor device may be a three-dimensional device, in which the transistors of the FEOL layer are vertically stacked. The lower active region LAR serving as a bottom tier or portion may be provided on the substrate 100, and the upper active region UAR serving as a top tier or portion may be stacked on the lower active region LAR. For example, the NMOSFET of the lower active region LAR may be provided on the substrate 100, and the PMOSFET of the upper active region UAR may be stacked on the NMOSFET. The lower and upper active regions LAR and UAR may be spaced apart from each other in a vertical direction (e.g., in a third direction D3).

Each of the lower and upper active regions LAR and UAR may have a first width W1 in the first direction D1. In the present embodiment, a length of the single height cell SHC in the first direction D1 may be defined as a second height HE2.

Since the single height cell SHC according to the present embodiment includes the three-dimensional device (i.e., the stacked transistors), the lower and upper active regions LAR and UAR may be overlapped by each other. Thus, the second height HE2 of the single height cell SHC may have a size spanning a single active region or may be larger than the first width W1. As a result, the second height HE2 of the single height cell SHC according to the present embodiment may be smaller than the first height HE1 of the single height cell SHC′ described with reference to FIG. 1. That is, the single height cell SHC in the present embodiment may have a relatively small area. In the three-dimensional semiconductor device according to the present embodiment, an integration density of the device may be increased by reducing an area of the logic cell.

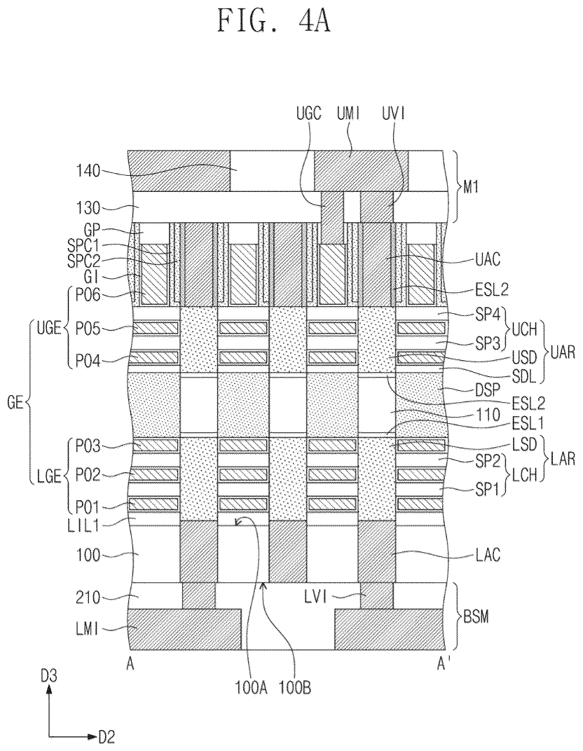

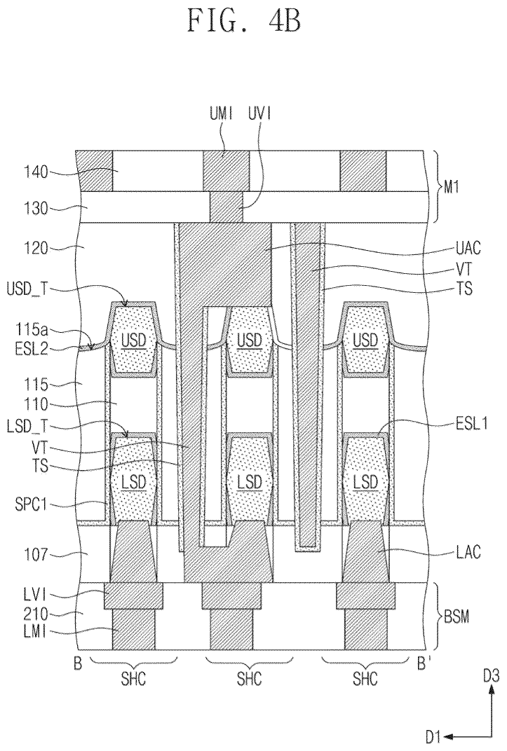

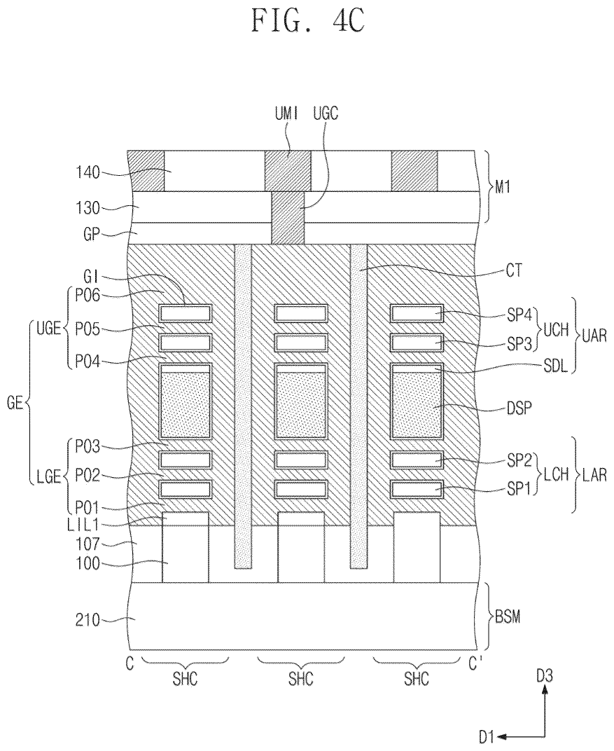

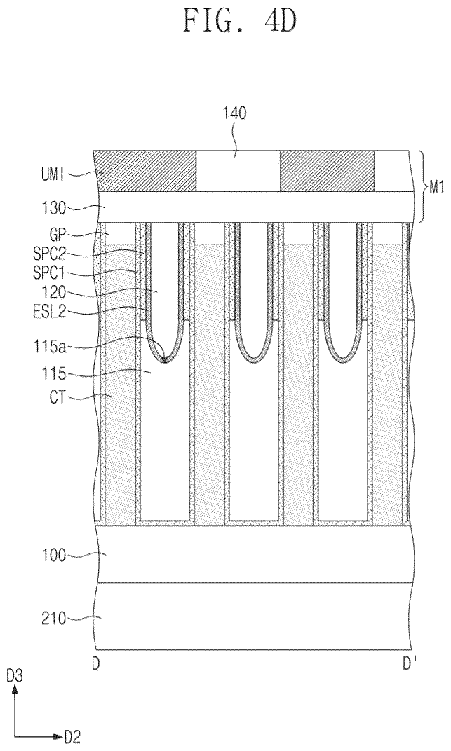

FIG. 3 is a plan view illustrating a three-dimensional semiconductor device according to an embodiment of the inventive concept. FIGS. 4A to 4C are sectional views taken along lines A-A′, B-B′, and C-C′ of FIG. 3. The three-dimensional semiconductor device of FIGS. 3 and 4A to 4C may be a detailed example of the single height cell of FIG. 2.

Referring to FIG. 3 and FIGS. 4A to 4D, the single height cells SHC may be provided on the substrate 100. The substrate 100 may include a first surface 100A and a second surface 100B, which are opposite to each other. The first surface 100A may be the front surface of the substrate 100, and the second surface 100B may be the rear surface of the substrate 100. In an embodiment, the substrate 100 may be an insulating substrate, which is formed of or includes a silicon-based insulating material (e.g., silicon oxide and/or silicon nitride). In an embodiment, the substrate 100 may be a semiconductor substrate made of silicon, germanium, or silicon germanium.

A device isolation layer 107 may be disposed in the substrate 100 and between the single height cells SHC. A top surface of the device isolation layer 107 may be coplanar with a top surface of the substrate 100. In an embodiment, the device isolation layer 107 may be formed of or include a silicon-based insulating material (e.g., silicon oxide, silicon oxynitride, or silicon nitride).

In an embodiment, each of the single height cells SHC may be a logic cell constituting a logic circuit. Each of the single height cells SHC may be a logic cell, which includes a three-dimensional device previously described with reference to FIG. 2. The single height cells SHC may be arranged in the first direction D1 and may be spaced apart from each other in the first direction D1.

Each of the single height cell SHC may include the lower and upper active regions LAR and UAR, which are sequentially stacked on the substrate 100. One of the lower and upper active regions LAR and UAR may be a PMOSFET region, and the other of the lower and upper active regions LAR and UAR may be an NMOSFET region. The lower active region LAR may be provided as a bottom tier or portion of the FEOL layer, and the upper active region UAR may be provided as a top tier or portion of the FEOL layer. The NMOSFET and PMOSFET of the lower and upper active regions LAR and UAR may be vertically stacked to constitute transistors, which are three-dimensionally stacked. In an embodiment, the lower active region LAR may be an NMOSFET region, and the upper active region UAR may be a PMOSFET region.

Each of the lower and upper active regions LAR and UAR may have a bar-shaped or line-shaped region, which is extended in a second direction D2. A cutting pattern CT may be provided between the single height cells SHC, which are adjacent to each other.

The cutting pattern CT may separate adjacent ones of the single height cells SHC from each other. The adjacent ones of the single height cells SHC may be spaced apart from each other in the first direction D1 by the cutting pattern CT. The cutting pattern CT may be a bar-shaped or line-shaped pattern that is extended in the second direction D2.

The lower active region LAR including lower channel patterns LCH and lower source/drain patterns LSD may be provided on the single height cell SHC. The lower channel pattern LCH may be interposed between a pair of the lower source/drain patterns LSD in the second direction D2. The lower channel pattern LCH may connect the pair of the lower source/drain patterns LSD to each other.

The lower channel pattern LCH may include a first semiconductor pattern SP1 and a second semiconductor pattern SP2, which are stacked to be spaced apart from each other in the third direction D3. Each of the first and second semiconductor patterns SP1 and SP2 may be formed of or include silicon (Si), germanium (Ge), or silicon germanium (SiGe). For example, each of the first and second semiconductor patterns SP1 and SP2 may include crystalline silicon. Each of the first and second semiconductor patterns SP1 and SP2 may be a nanosheet. In an embodiment, the lower channel pattern LCH may further include one or more semiconductor patterns, which are stacked to be spaced apart from the first semiconductor pattern SP1. The first semiconductor pattern SP1 may be the lowest one of the semiconductor patterns.

The lower source/drain patterns LSD may be provided on the substrate 100. Each of the lower source/drain patterns LSD may be an epitaxial pattern that is formed by a selective epitaxial growth (SEG) process. In an embodiment, a level of a top surface of the lower source/drain pattern LSD in the third direction D3 relative to the rear surface 100b of the substrate 100 may be higher than a level of a top surface of the second semiconductor pattern SP2 of the lower channel pattern LCH in the third direction D3 relative to the rear surface 100b of the substrate 100.

As used herein, “a level of a first surface in a given direction (e.g., the third direction D3) relative to a reference surface (e.g., the rear surface 100b of the substrate 100) that is higher than a level of a second surface in the given direction relative to the reference surface” refers to a distance between the first surface and the reference surface in the given direction being greater than a distance between the second surface and the reference surface in the given direction.

The lower source/drain patterns LSD may be doped with impurities to have a first conductivity type. The first conductivity type may be an n-type or p-type. In the present embodiment, the first conductivity type may be an n-type. The lower source/drain patterns LSD may be formed of or include silicon (Si) and/or silicon germanium (SiGe).

A first etch stop layer ESL1 may be provided on the lower source/drain patterns LSD (e.g., see FIG. 4B). A first interlayer insulating layer 110 may be provided on the first etch stop layer ESL1. The first interlayer insulating layer 110 may cover or overlap the first etch stop layer ESL1 and the lower source/drain patterns LSD in the third direction D3.

A lower active contact LAC may be provided below the lower source/drain pattern LSD. The lower active contact LAC may be electrically connected to the lower source/drain pattern LSD. In an embodiment, the lower active contact LAC may be extended to a region on the first surface 100A of the substrate 100. In another embodiment, the lower active contact LAC may be buried in the substrate 100 and may be vertically extended from the second surface 100B of the substrate 100 to the first surface 100A. The lower active contact LAC may be formed of or include a metallic material that is selected from the group consisting of copper (Cu), aluminum (Al), ruthenium (Ru), cobalt (Co), tungsten (W), and molybdenum (Mo).

The upper active region UAR may be provided on the first interlayer insulating layer 110. The upper active region UAR may include upper channel patterns UCH and upper source/drain patterns USD. The upper channel patterns UCH may be vertically overlapped (e.g., overlapped in the third direction D3) by the lower channel patterns LCH, respectively. The upper source/drain patterns USD may be vertically overlapped (e.g., overlapped in the third direction D3) by the lower source/drain patterns LSD, respectively. The upper channel pattern UCH may be interposed between a pair of the upper source/drain patterns USD in the second direction D2. The upper channel pattern UCH may connect the pair of the upper source/drain patterns USD to each other.

The upper channel pattern UCH may include a third semiconductor pattern SP3 and a fourth semiconductor pattern SP4, which are stacked to be spaced apart from each other in the third direction D3. The third and fourth semiconductor patterns SP3 and SP4 of the upper channel pattern UCH may include the same semiconductor material as the first and second semiconductor patterns SP1 and SP2 of the lower channel pattern LCH. Each of the third and fourth semiconductor patterns SP3 and SP4 may be a nanosheet. In an embodiment, the upper channel pattern UCH may further include one or more semiconductor patterns, which are stacked to be spaced apart from the third semiconductor pattern SP3.

At least one dummy channel pattern DSP may be interposed between the lower channel pattern LCH and the upper channel pattern UCH in the third direction D3. A seed layer SDL may be interposed between the dummy channel pattern DSP and the upper channel pattern UCH in the third direction D3.

The dummy channel pattern DSP may be spaced apart from the lower and upper source/drain patterns LSD and USD. That is, the dummy channel pattern DSP may not be connected to any source/drain pattern. The dummy channel pattern DSP may include a semiconductor material (e.g., silicon (Si), germanium (Ge) or silicon germanium (SiGe)) or may include a silicon-based insulating material (e.g., silicon oxide or silicon nitride). In an embodiment, the dummy channel pattern DSP may be formed of or include the silicon-based insulating material.

The upper source/drain patterns USD may be provided on a top surface of the first interlayer insulating layer 110. Each of the upper source/drain patterns USD may be an epitaxial pattern that is formed by a selective epitaxial growth (SEG) process. In an embodiment, a level of a top surface of the upper source/drain pattern USD in the third direction D3 may be higher than a level of a top surface of the fourth semiconductor pattern SP4 of the upper channel pattern UCH relative to the rear surface 100b of the substrate 100 in the third direction D3.

The upper source/drain patterns USD may be doped with impurities to have a second conductivity type. The second conductivity type may be different from the first conductivity type of the lower source/drain pattern LSD. The second conductivity type may be a p-type. The upper source/drain patterns USD may be formed of or include silicon germanium (SiGe) and/or silicon (Si).

A gapfill insulating pattern 115 may be provided on the substrate 100 and the device isolation layer 107. The gapfill insulating pattern 115 may be positioned between the lower source/drain patterns LSD, which are adjacent to each other in the first direction D1. The gapfill insulating pattern 115 may be extended in a vertical direction (e.g., the third direction D3) to be adjacent to (or at least overlap a portion of in the first direction D1) a side surface of the lower source/drain pattern LSD and a side surface of the upper source/drain pattern USD. That is, the gapfill insulating pattern 115 (e.g., a side surface of the gapfill insulating pattern 115) may be provided to face the side surface of the lower source/drain pattern LSD and the side surface of the upper source/drain pattern USD. In an embodiment, the gapfill insulating patterns 115 may be provided to be spaced apart from each other in the first and second directions D1 and D2.

The gapfill insulating pattern 115 may have a recessed top surface 115a (e.g., see FIG. 4B). The profile of the recessed top surface 115a of the gapfill insulating pattern 115 may be a result that is obtained by a step of forming a recess in a subsequent fabrication process. The recessed top surface 115a of the gapfill insulating pattern 115 may be rounded. A level of the recessed top surface 115a of the gapfill insulating pattern 115 in the third direction D3 is higher than a level of the uppermost portion LSD_T of the lower source/drain pattern LSD relative to the rear surface 100b of the substrate 100 and is lower than a level of the uppermost portion USD_T of the upper source/drain pattern USD relative to the rear surface 100b of the substrate 100. That is, a distance between the recessed top surface 115a and the rear surface 100b in the third direction D3 is greater than a distance between the uppermost portion LSD_T of the lower source/drain pattern LSD and the rear surface 100b in the third direction D3, and a distance between the recessed top surface 115a and the rear surface 100b in the third direction D3 is less than a distance between the uppermost portion USD_T of the upper source/drain pattern USD and the rear surface 100b in the third direction D3. In an embodiment, a level of the recessed top surface 115a of the gapfill insulating pattern 115 in the third direction D3 may be between a level of the uppermost portion USD_T and a level of the lowermost portion of the upper source/drain pattern USD in the third direction D3. The uppermost portion USD_T of the upper source/drain pattern USD may be a portion of the upper source/drain pattern USD that is at the highest level of the upper source/drain pattern USD in the vertical direction, and the uppermost portion LSD_T of the lower source/drain pattern LSD may be a portion of the lower source/drain pattern LSD that is at the highest level of the lower source/drain pattern LSD in the vertical direction. Similarly, the lowermost portion of the upper source/drain pattern USD may be a portion of the upper source/drain pattern USD that is at the lowest level of the upper source/drain pattern USD in the vertical direction, and the lowermost portion of the lower source/drain pattern LSD may be a portion of the lower source/drain pattern LSD that is at the lowest level of the lower source/drain pattern LSD in the vertical direction. In an embodiment, the gapfill insulating pattern 115 may be formed of or include a silicon-based insulating material (e.g., silicon oxide, silicon oxynitride, or silicon nitride). The recessed top surface 115a may face the substrate 100 and overlap at least a portion of the upper source/drain pattern USD in the second direction D2.

A first spacer SPC1 may be provided to cover or overlap side and bottom surfaces of the gapfill insulating pattern 115 in the first direction D1 and the third direction D3, respectively. In an embodiment, the first spacer SPC1 may be interposed between the side surface of the gapfill insulating pattern 115 and the side surface of the lower source/drain pattern LSD in the first direction D1 and between the bottom surface of the gapfill insulating pattern 115 and the substrate 100 and the device isolation layer 107 in the third direction D3. In other words, the first spacer SPC1 may cover or overlap the substrate 100 and the top surface of the device isolation layer 107 in the third direction D3 and may be vertically extended along the side surface of the gapfill insulating pattern 115 to be in contact with side surfaces of the lower source/drain pattern LSD, the first interlayer insulating layer 110, the upper source/drain pattern USD, first and second etch stop layers ESL1 and ELS2, and the cutting pattern CT. As will be described below, the first spacer SPC1 may partially prevent or inhibit a stacking pattern STP from being oxidized by the gapfill insulating pattern 115 in a fabrication process. In an embodiment, the first spacer SPC1 may be formed of or include at least one of SiCN, SiCON, or SiN.

A second etch stop layer ESL2 may be provided on the upper source/drain patterns USD. In an embodiment, the second etch stop layer ESL2 may be interposed between the upper source/drain pattern USD and the first interlayer insulating layer 110 in the third direction D3. The second etch stop layer ESL2 may cover or overlap the recessed top surface 115a of the gapfill insulating pattern 115 in the third direction D3. In other words, the gapfill insulating pattern 115 may be spaced apart from a second interlayer insulating layer 120, which will be described below, with the second etch stop layer ESL2 interposed therebetween in the third direction D3.

A plurality of gate electrodes GE may be provided on the single height cell SHC. In detail, the gate electrode GE may be provided on the stacked lower and upper channel patterns LCH and UCH (e.g., see FIG. 4A). When viewed in a plan view, the gate electrode GE may be a bar-shaped pattern, which is extended in the first direction D1. The gate electrode GE may be vertically overlapped (e.g., overlapped in the third direction D3) by the stacked lower and upper channel patterns LCH and UCH.

The gate electrode GE may be extended from the first surface 100A of the substrate 100 to a gate capping pattern GP in a vertical direction (i.e., the third direction D3). The gate electrode GE may be extended from the lower channel pattern LCH of the lower active region LAR to the upper channel pattern UCH of the upper active region UAR in the third direction D3. The gate electrode GE may be extended from the lowermost semiconductor pattern (i.e., the first semiconductor pattern SP1) to the uppermost semiconductor pattern (i.e., the fourth semiconductor pattern SP4) in the third direction D3.

The gate electrode GE may be provided on a top surface, a bottom surface, and opposite side surfaces of each of the first to fourth semiconductor patterns SP1, SP2, SP3, and SP4 (e.g., see FIG. 4C). That is, the transistor according to the present embodiment may include a three-dimensional field effect transistor (e.g., MBCFET or GAAFET) in which the gate electrode GE is provided to three-dimensionally surround at least a portion of the channel pattern.

The gate electrode GE may include a lower gate electrode LGE provided in the lower active region LAR and an upper gate electrode UGE provided in the upper active region UAR. The lower gate electrode LGE and the upper gate electrode UGE may be overlapped by each other in the third direction D3 (e.g., when viewed in a plan view). In an embodiment, the lower gate electrode LGE and the upper gate electrode UGE may be connected to each other. That is, the gate electrode GE according to the present embodiment may be a common gate electrode, in which the lower gate electrode LGE on the lower channel pattern LCH and the upper gate electrode UGE on the upper channel pattern UCH are connected to each other.

The lower gate electrode LGE may include a first inner electrode PO1 interposed between a first active pattern AP1 and the first semiconductor pattern SP1 in the third direction D3, a second inner electrode PO2 interposed between the first semiconductor pattern SP1 and the second semiconductor pattern SP2 in the third direction D3, and a third inner electrode PO3 interposed between the second semiconductor pattern SP2 and the dummy channel pattern DSP in the third direction D3.

The upper gate electrode UGE may include a fourth inner electrode PO4 interposed between the dummy channel pattern DSP (or the seed layer SDL) and the third semiconductor pattern SP3 in the third direction D3, a fifth inner electrode PO5 interposed between the third semiconductor pattern SP3 and the fourth semiconductor pattern SP4 in the third direction D3, and an outer electrode PO6, which is placed at the uppermost level of the upper gate electrode UGE and is placed on the fourth semiconductor pattern SP4.

Referring to FIGS. 3 and 4A, a pair of first spacers SPC1 and a pair of second spacers SPC2 may be respectively disposed on opposite side surfaces of the outer electrode PO6. In an embodiment, the first spacer SPC1 may be disposed on the side surface of the outer electrode PO6, and the second spacer SPC2 may be disposed on the side surface of the first spacer SPC1. The second spacer SPC2 may be in contact with the side surface of the first spacer SPC1.

The first and second spacers SPC1 and SPC2 may be extended along the gate electrode GE and in the first direction D1. Top surfaces of the first and second spacers SPC1 and SPC2 may be located at a level in the third direction D3 that is higher than a level of a top surface of the outer electrode PO6 in the third direction D3. For example, the top surfaces of the first spacers SPC1 may be coplanar with a top surface of a gate capping pattern GP to be described below.

In an embodiment, the second spacers SPC2 may be formed of or include at least one of SiCN, SiCON, or SiN. Furthermore, the second spacers SPC2 may further include a low-k dielectric material (e.g., the air or porous layer). In other words, a dielectric constant of the second spacers SPC2 may be lower than a dielectric constant of the first spacers SPC1.

The gate capping pattern GP may be provided on the top surface of the gate electrode GE. The gate capping pattern GP may be extended along the gate electrode GE or in the first direction D1. For example, the gate capping pattern GP may be formed of or include at least one of SiON, SiCN, SiCON, or SiN. The second etch stop layer ESL2 may be provided on the gate capping pattern GP and the second spacers SPC2. That is, the second etch stop layer ESL2 may cover or overlap at least a portion of side surfaces of the second spacers SPC2 in the second direction D2.

A gate insulating layer GI may be interposed between the gate electrode GE and the first to fourth semiconductor patterns SP1, SP2, SP3, and SP4. The gate insulating layer GI may be formed of or include at least one of silicon oxide, silicon oxynitride, and/or high-k dielectric materials. In an embodiment, the gate insulating layer GI may include a silicon oxide layer, which is formed to directly cover or surround the semiconductor patterns SP1 to SP4, and a high-k dielectric layer, which is formed on the silicon oxide layer. In other words, the gate insulating layer GI may be a multi-layered structure including the silicon oxide layer and the high-k dielectric layer.

The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The lower gate electrode LGE may include a first work function metal pattern on the first and second semiconductor patterns SP1 and SP2. The upper gate electrode UGE may include a second work function metal pattern on the third and fourth semiconductor patterns SP3 and SP4. Each of the first and second work function metal patterns may be formed of a material, which includes at least one metallic element, which is selected from the group consisting of titanium (Ti), tantalum (Ta), aluminum (Al), tungsten (W), and molybdenum (Mo), and nitrogen (N). The first and second work function metal patterns may have different work functions from each other. The gate electrode GE may include at least one of low resistance metals (e.g., tungsten (W), ruthenium (Ru), aluminum (Al), titanium (Ti), and tantalum (Ta)) on the first and second work function metal patterns. For example, the outer electrode PO6 may include the second work function metal pattern as well as the low resistance metal.

The second interlayer insulating layer 120 may cover or overlap at least a portion of the upper source/drain patterns USD in the third direction D3. A top surface of the second interlayer insulating layer 120 may be coplanar with a top surface of each of upper active contacts UAC, which will be described below.

An upper gate contact UGC may be provided to penetrate or extend into a third interlayer insulating layer 130 and the gate capping pattern GP and may be electrically connected to the upper gate electrode UGE. For example, the upper gate electrode UGC may be in contact with a top surface of the upper source/drain pattern USD. Each of the upper active contact UAC and the upper gate contact UGC may be formed of or include a metallic material that is selected from the group consisting of copper (Cu), aluminum (Al), ruthenium (Ru), cobalt (Co), tungsten (W), and molybdenum (Mo).

The cutting pattern CT may be provided between the gate electrodes GE, which are adjacent to each other in the first direction D1. The cutting pattern CT may separate the adjacent ones of the gate electrodes GE from each other. The adjacent ones of the gate electrodes GE may be spaced apart from each other, in the first direction D1, by the cutting pattern CT. The cutting pattern CT may be a bar-shaped or line-shaped pattern that is extended in the second direction D2. The cutting pattern CT may include a single insulating layer or a plurality of insulating layers.

Vertical vias VT may be provided to vertically penetrate or extend into the second interlayer insulating layer 120 and the gapfill insulating pattern 115. A penetration spacer TS may be disposed between the vertical via VT and the second interlayer insulating layer 120 in the second direction D2 and between the vertical via VT and the gapfill insulating pattern 115 in the second direction D2. In an embodiment, the penetration spacer TS may be an insulating layer (e.g., a silicon nitride layer).

The vertical vias VT may be provided to penetrate or extend into the second interlayer insulating layer 120 and the gapfill insulating pattern 115 and to electrically connect a first metal layer M1 to a back-side metal layer BSM. A width of the vertical vias VT may gradually increase as a distance from a bottom surface of the vertical via VT increases in a vertical direction D3.

The vertical via VT may connect the upper active contact UAC to the lower active contact LAC. The vertical via VT may be connected to a portion of each of the upper and lower active contacts UAC and LAC. For example, the upper active contact UAC may be extended in the first direction D1 and may be connected to an upper portion of the vertical via VT, and the lower active contact LAC may be extended in the first direction D1 and may be connected to a lower portion of the vertical via VT.

The vertical via VT may include a metallic material. For example, the vertical via VT may be formed of or include at least one of copper (Cu), aluminum (Al), ruthenium (Ru), cobalt (Co), tungsten (W), or molybdenum (Mo).

The third interlayer insulating layer 130 may be provided on the second interlayer insulating layer 120. The first metal layer M1 may be provided in the third interlayer insulating layer 130. The first metal layer M1 may include upper interconnection lines UMI. The first metal layer M1 may further include an upper via UVI. The upper via UVI may electrically connect the upper interconnection line UMI to the upper active contact UAC or the upper gate contact UGC. Each of the upper interconnection line UMI and the upper via UVI may be formed of or include a metallic material that is selected from the group consisting of copper (Cu), aluminum (Al), ruthenium (Ru), cobalt (Co), tungsten (W), and molybdenum (Mo).

Additional metal layers (not shown) may be stacked on the first metal layer M1. The first metal layer M1 and the additional metal layers on the first metal layer M1 may constitute a back-end-of-line (BEOL) layer of the semiconductor device. The metal layers on the first metal layer M1 may include routing interconnection lines, which are used to connect the logic cells to each other.

A first lower interlayer insulating layer 210 may be provided below the second surface 100B of the substrate 100. The back-side metal layer BSM may be provided in the first lower interlayer insulating layer 210. The back-side metal layer BSM may include lower interconnection lines LMI. The back-side metal layer BSM may further include a lower via LVI. The lower via LVI may be provided to electrically connect one of the lower active and gate contacts LAC and LGC to the lower interconnection line LMI. Each of the lower interconnection line LMI and the lower via LVI may be formed of or include a metallic material that is selected from the group consisting of copper (Cu), aluminum (Al), ruthenium (Ru), cobalt (Co), tungsten (W), and molybdenum (Mo).

Lower metal layers may be further stacked below the back-side metal layer BSM. In an embodiment, the lower metal layers may include a power delivery network. The power delivery network may include a wiring network, which is used to apply source and drain voltages VSS and VDD to the back-side metal layer BSM.

The source and drain voltages VSS and VDD may be applied to the back-side metal layer BSM through the power delivery network. Referring back to FIG. 4A, one of the source and drain voltages VSS and VDD may be applied to the lower source/drain pattern LSD through the lower interconnection line LMI, the lower via LVI, and the lower active contact LAC. The other of the source and drain voltages VSS and VDD may be applied from the back-side metal layer BSM to the first metal layer M1 through a power tap cell. A voltage, which is applied to the first metal layer M1 through the power tap cell, may be applied to the upper source/drain pattern USD through the upper interconnection line UMI, the upper via UVI, and the upper active contact UAC. The power tap cell may be interposed between the single height cells SHC, which are adjacent to each other.

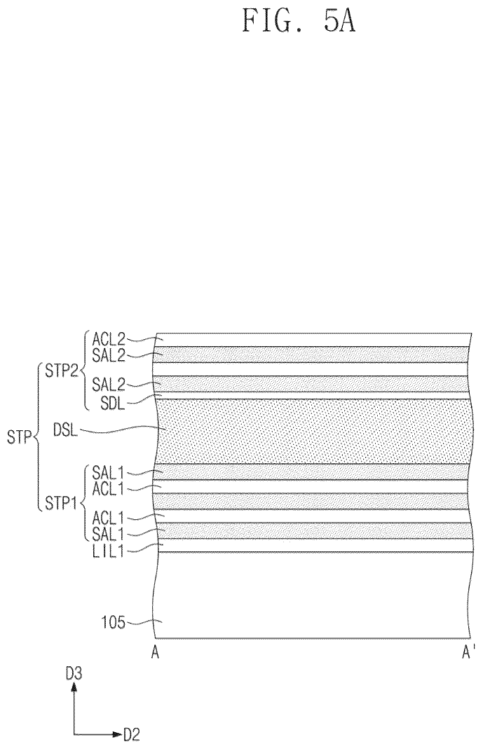

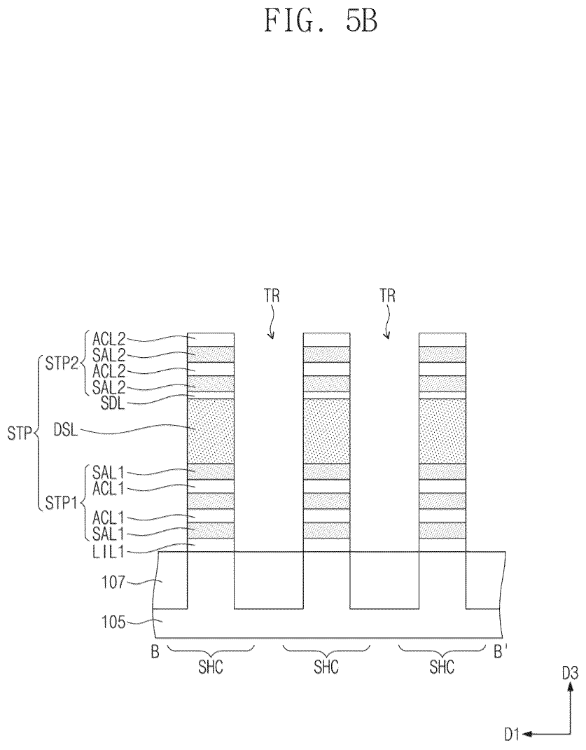

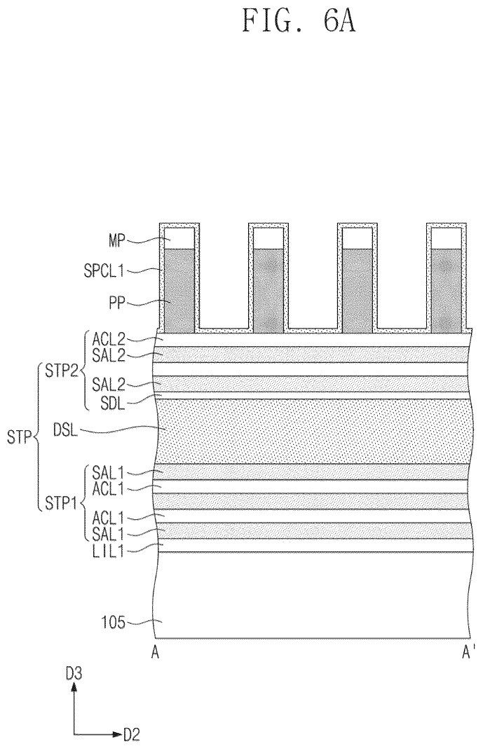

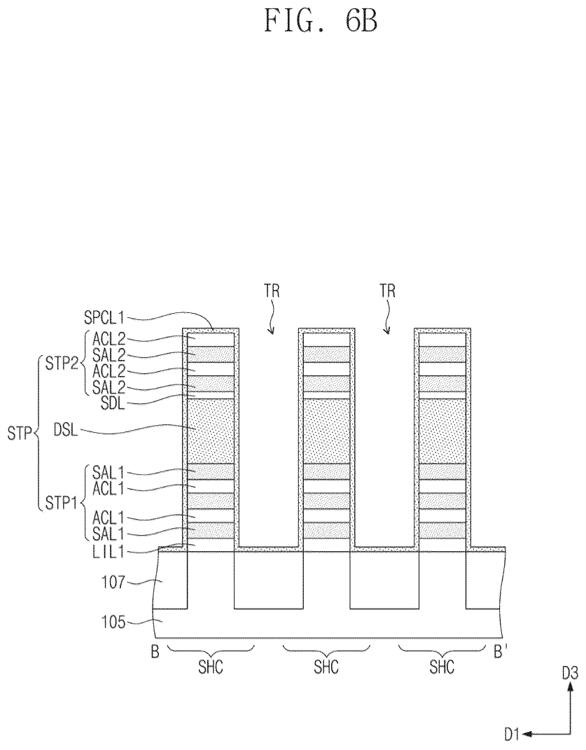

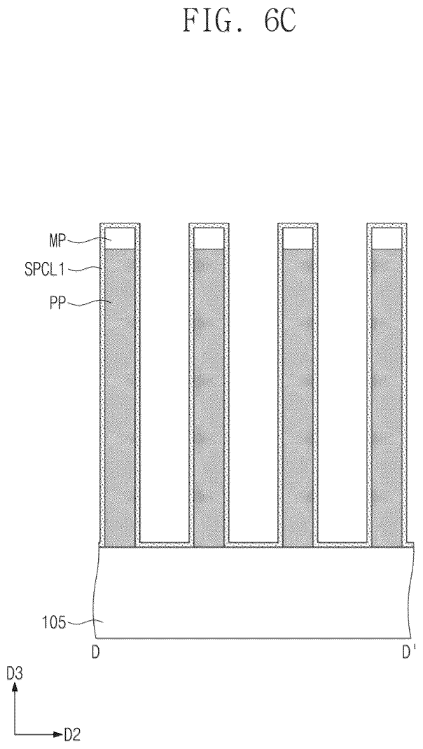

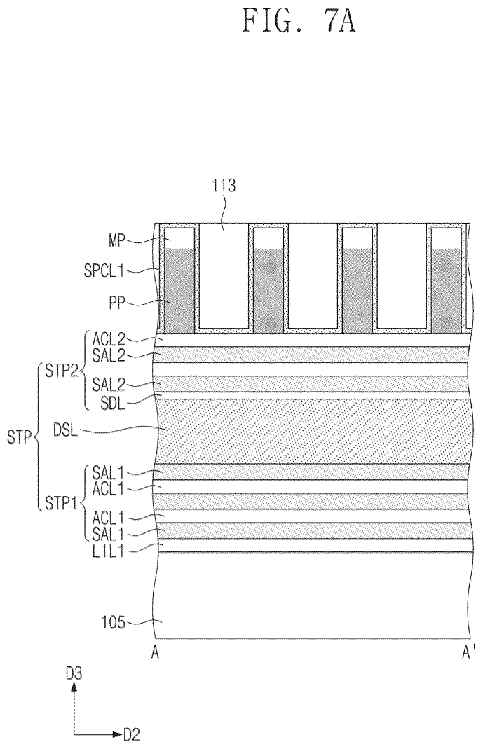

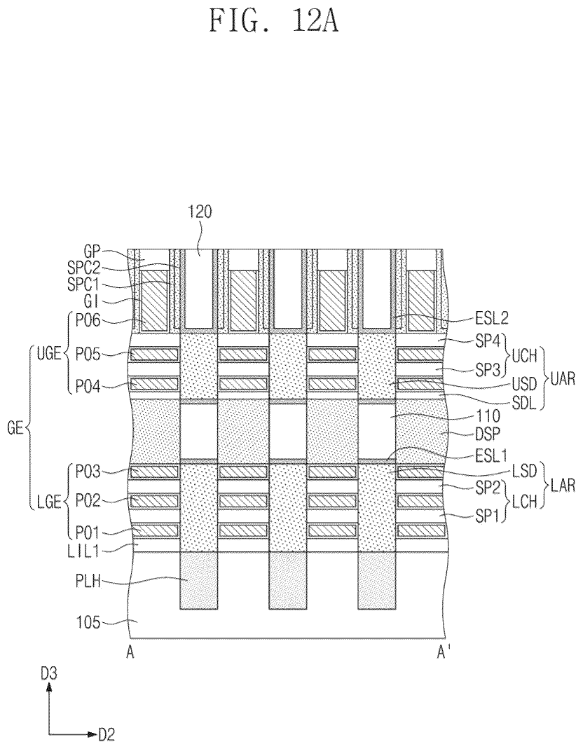

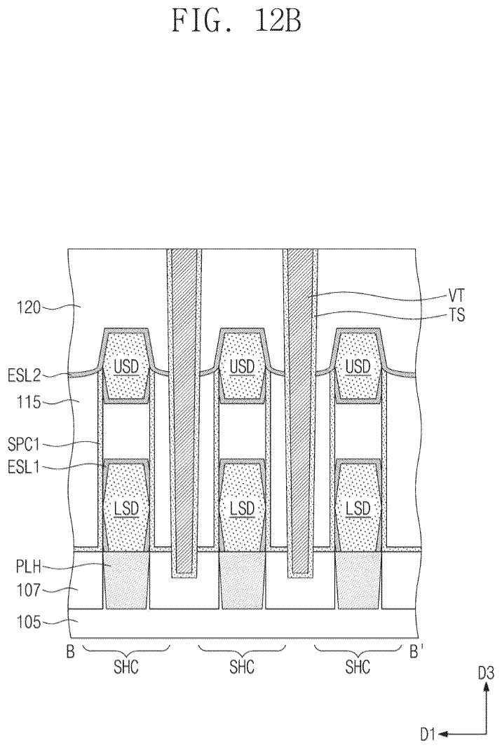

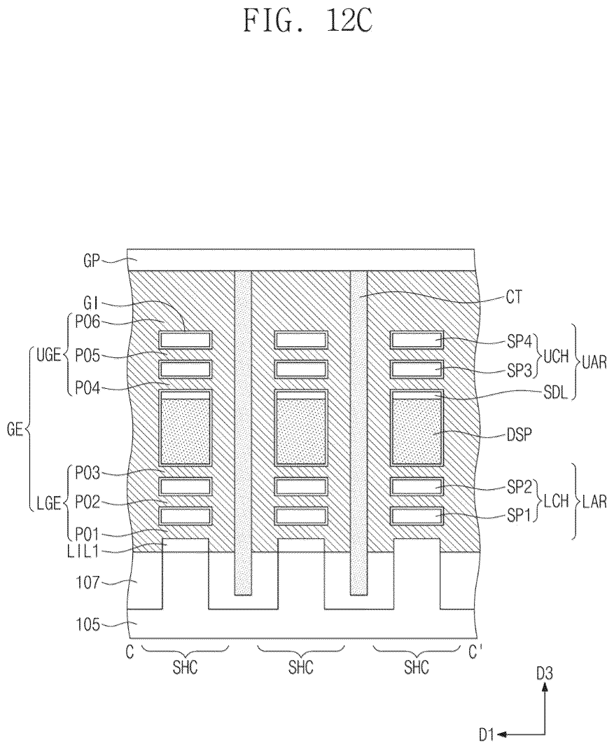

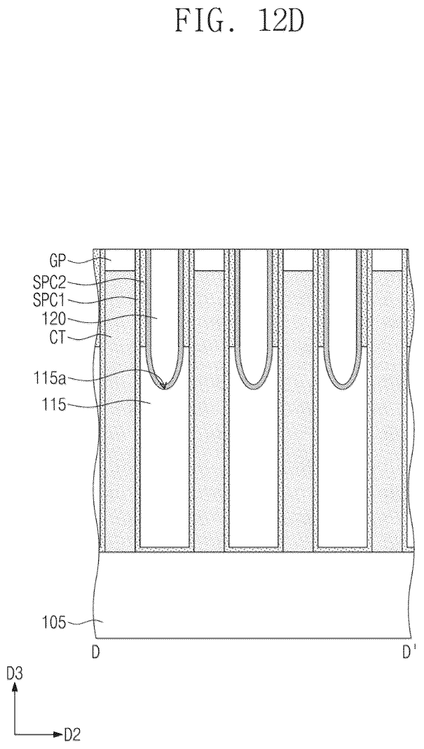

FIGS. 5A to 14D are sectional views illustrating a method of fabricating a semiconductor device according to an embodiment of the inventive concept. In detail, FIGS. 5A, 6A, 7A, 8A, 9A, 10A, 11A, 12A, 13A, and 14A are sectional views taken along the line A-A′ of FIG. 3. FIGS. 6B, 7B, 8B, 9B, 10B, 11B, 12B, 13B, and 14B are sectional view taken along the line B-B′ of FIG. 3. FIGS. 12C, 13C, and 14C are sectional views taken along the line C-C′ of FIG. 3. FIGS. 6C, 7C, 8C, 9C, 11C, 12D, 13D, and 14D are sectional views taken along lines D-D′ of FIG. 4.

Referring to FIGS. 5A and 5B, a semiconductor substrate 105 may be provided. The semiconductor substrate 105 may be formed of or include one of silicon (Si), germanium (Ge), and silicon-germanium (SiGe). For example, the semiconductor substrate 105 may be a single-crystalline silicon wafer.

A first lower insulating layer LIL1 may be formed on the semiconductor substrate 105. The first lower insulating layer LIL1 may include a silicon-based insulating material (e.g., silicon oxide) and/or a semiconductor material (e.g., Si or SiGe).

First sacrificial layers SAL1 and first active layers ACL1 may be alternatively stacked on the first lower insulating layer LIL1. For example, the first sacrificial layers SAL1 may be formed of or include silicon germanium (SiGe), and the first active layers ACL1 may be formed of or include silicon (Si). A concentration of germanium (Ge) in each of the first sacrificial layers SAL1 may range from 10 at % to 30 at %.

A separation layer DSL may be formed on the uppermost one of the first sacrificial layers SAL1. In an embodiment, a thickness of the separation layer DSL in the third direction D3 may be larger than a thickness of the first sacrificial layer SAL1 in the third direction D3. The separation layer DSL may be formed of or include silicon germanium (SiGe). A germanium concentration of the separation layer DSL may be higher than a germanium concentration of the first sacrificial layer SAL1. For example, the germanium concentration of the separation layer DSL may range from 40 at % to 90 at %.

The seed layer SDL may be formed on the separation layer DSL. The seed layer SDL may include the same material as the first active layer ACL1. Second sacrificial layers SAL2 and second active layers ACL2 may be alternatively stacked on the seed layer SDL. Each of the second sacrificial layers SAL2 may include the same material as the first sacrificial layer SAL1, and each of the second active layers ACL2 may include the same material as the first active layer ACL1. The separation layer DSL may be interposed between the first sacrificial layer SAL1 and the seed layer SDL.

The stacking pattern STP may be formed by patterning the first and second sacrificial layers SAL1 and SAL2, the first and second active layers ACL1 and ACL2, and the separation layer DSL which are stacked. The formation of the stacking pattern STP may include forming a hard mask pattern on the uppermost one of the second active layers ACL2, and etching the layers SAL1, SAL2, ACL1, ACL2, SDL, and DSL, which are stacked on the semiconductor substrate 105, using the hard mask pattern as an etch mask. During the formation of the stacking pattern STP, an upper portion of the semiconductor substrate 105 may be patterned to form a trench TR defining the single height cell SHC. The stacking pattern STP may be a bar-shaped or line-shaped pattern that is extended in the second direction D2.

The stacking pattern STP may include a lower stacking pattern STP1 on the first lower insulating layer LIL1, an upper stacking pattern STP2 on the lower stacking pattern STP1, and the separation layer DSL between the lower and upper stacking patterns STP1 and STP2. The lower stacking pattern STP1 may include the first sacrificial layers SAL1 and the first active layers ACL1, which are alternately stacked. The upper stacking pattern STP2 may include the seed layer SDL and the second sacrificial and active layers SAL2 and ACL2, which are alternately stacked on the seed layer SDL.

Thereafter, the device isolation layer 107 may be formed on the semiconductor substrate 105 to fill a portion of the trench TR. The formation of the device isolation layer 107 may include forming an insulating layer on the semiconductor substrate 105 to cover the stacking patterns STP and recessing the insulating layer to expose the side surfaces of the stacking patterns STP. The top surface of the device isolation layer 107 may be coplanar with a top surface of the semiconductor substrate 105.

Referring to FIGS. 6A, 6B, and 6C, a plurality of sacrificial patterns PP may be formed to cross the stacking pattern STP. Each of the sacrificial patterns PP may be formed on the stacking pattern STP and the semiconductor substrate 105 and may be a line-shaped pattern extended in the first direction D1. In detail, the formation of the sacrificial pattern PP may include forming a sacrificial layer on the semiconductor substrate 105, forming a hard mask pattern MP on the sacrificial layer, and patterning the sacrificial layer using the hard mask pattern MP as an etch mask. The sacrificial layer may be formed of or include amorphous silicon and/or polysilicon.

Thereafter, a first spacer layer SPCL1 may be conformally formed on the stacking pattern STP, the sacrificial patterns PP, the hard mask patterns MP, and the device isolation layer 107. In detail, the first spacer layer SPCL1 may conformally cover or overlap at least a portion of the structure provided on the semiconductor substrate 105 in the first, second, and third directions D1, D2, D3. For example, the first spacer layer SPCL1 may be formed of or include at least one of SiCN, SiCON, or SiN. The first spacer layer SPCL1 may cover a side surface of the stacking pattern STP and a side surface of the sacrificial pattern PP and may cover a top surface of a second active layer ALC2.

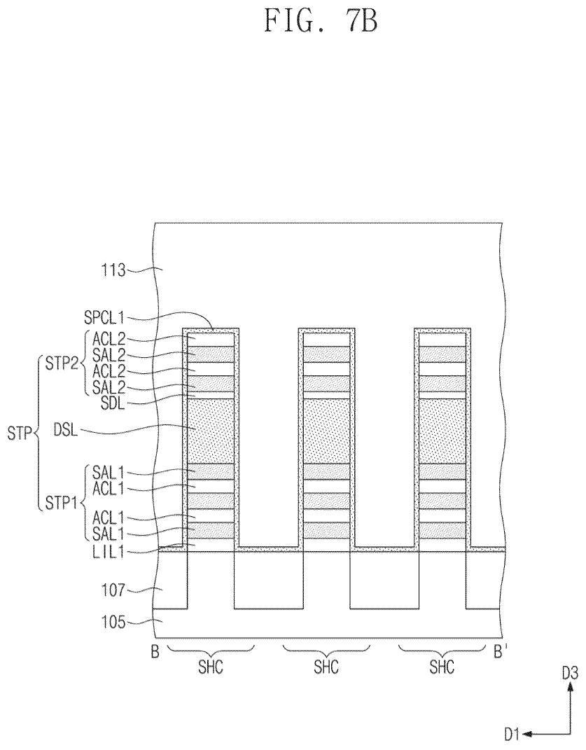

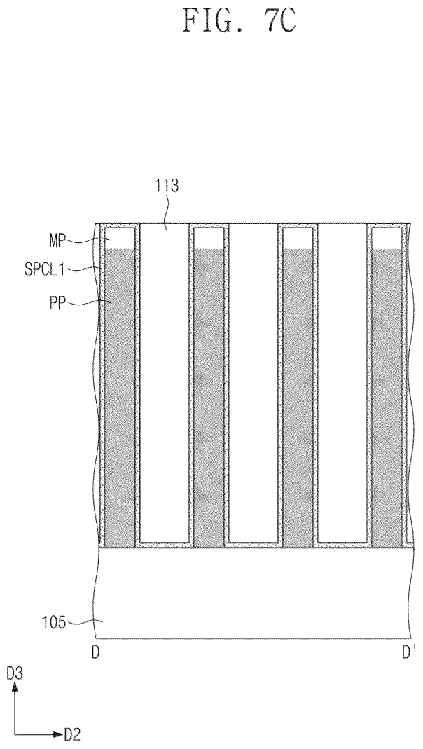

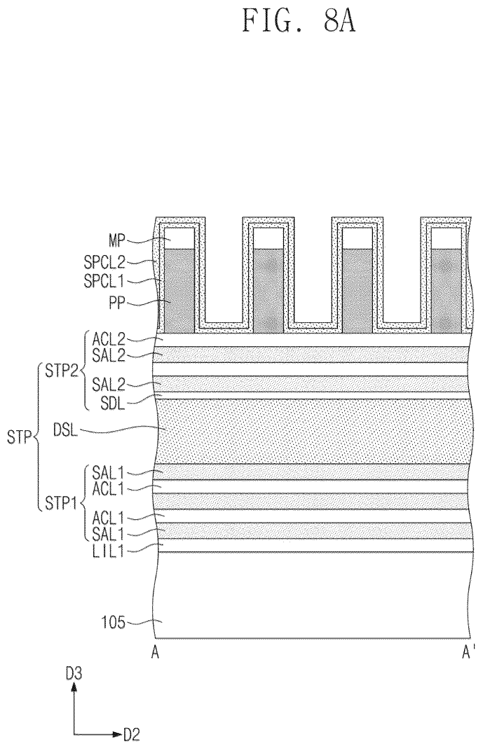

Referring to FIGS. 7A, 7B, and 7C, a preliminary insulating gapfill layer 113 may be formed to cover or overlap at least a portion of the stacking pattern STP in the first, second, and third directions D1, D2, D3 and at least a portion of the semiconductor substrate 105 in the third direction D3. The preliminary insulating gapfill layer 113 may fill at least a portion of the trench TR between the stacking pattern STP. The formation of the preliminary insulating gapfill layer 113 may include forming an insulating layer on the semiconductor substrate 105, performing a densification process on the insulating layer, and performing a planarization process to partially expose a top surface of the first spacer layer SPCL1. The preliminary insulating gapfill layers 113 may be coplanar with the uppermost portion of the top surface of the first spacer layer SPCL1 and may be spaced apart from each other in the second direction D2.

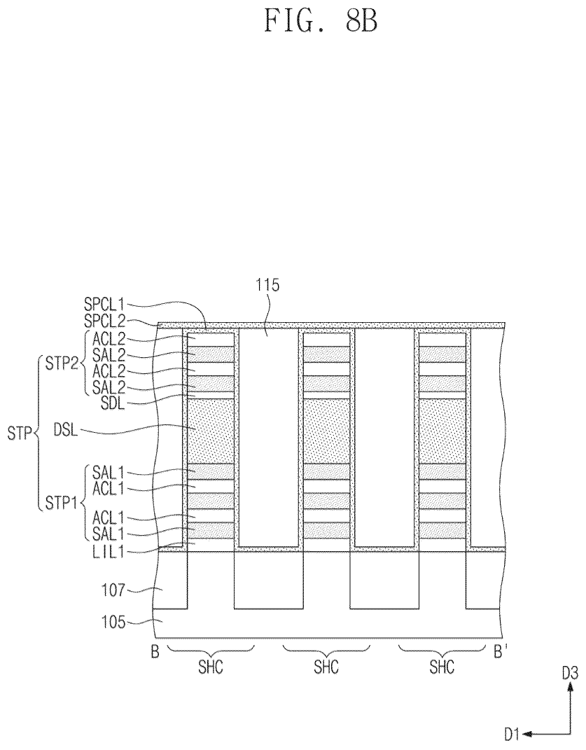

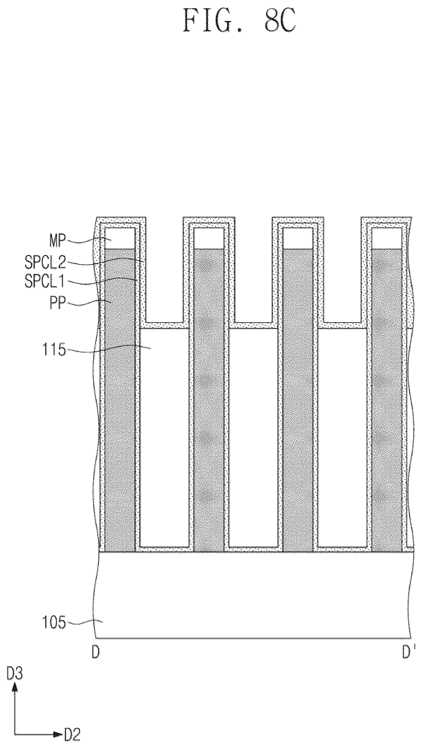

Referring to FIGS. 8A, 8B, and 8C, the preliminary insulating gapfill layer 113 may be partially etched to form the gapfill insulating pattern 115. In an embodiment, the gapfill insulating pattern 115 may be formed through an etch-back process, and a top surface of the gapfill insulating pattern 115 may be coplanar with a top surface of the stacking pattern STP. Accordingly, the gapfill insulating patterns 115 may be spaced apart from each other, in the first direction D1, with the stacking pattern STP interposed therebetween.

A second spacer layer SPCL2 may be formed on the gapfill insulating pattern 115 and the first spacer layer SPCL1. The second spacer layer SPCL2 may conformally cover or overlap the gapfill insulating pattern 115 in the third direction D3 and the first spacer layer SPCL1 in the first, second, and third directions D1, D2, D3. In an embodiment, the second spacers SPC2 may be formed of or include at least one of SiCN, SiCON, SiN, or low-k dielectric materials.

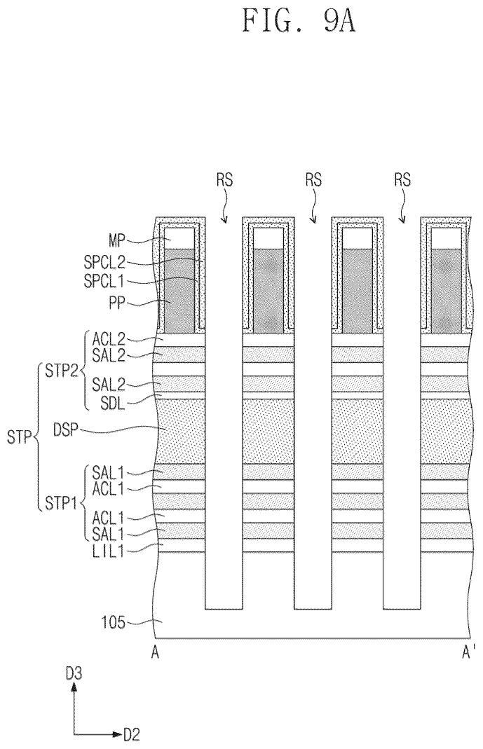

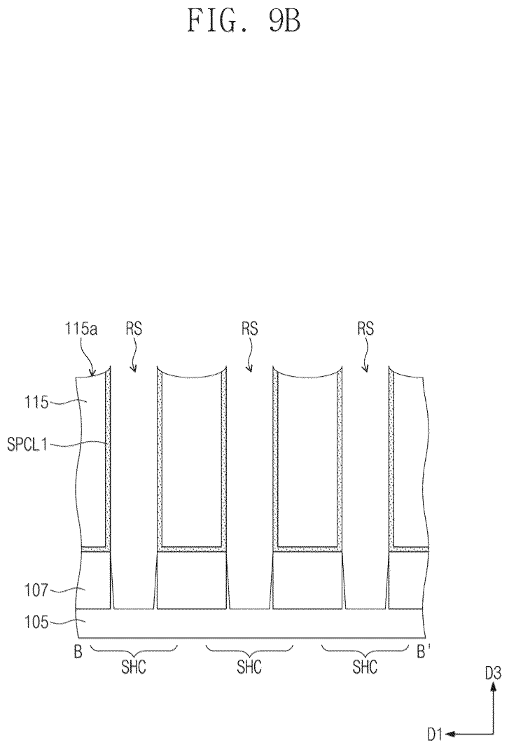

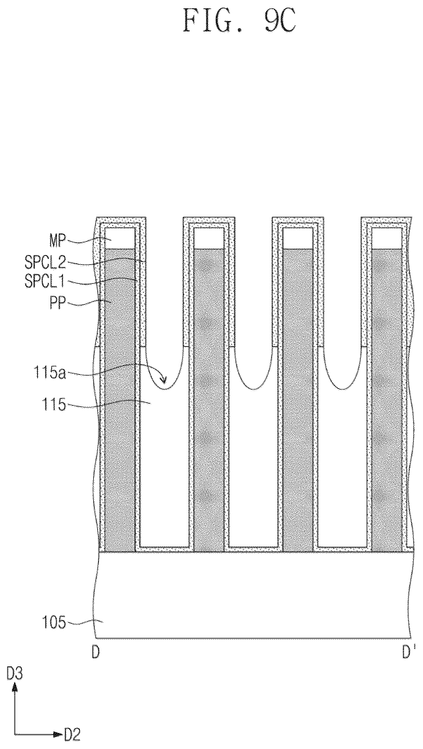

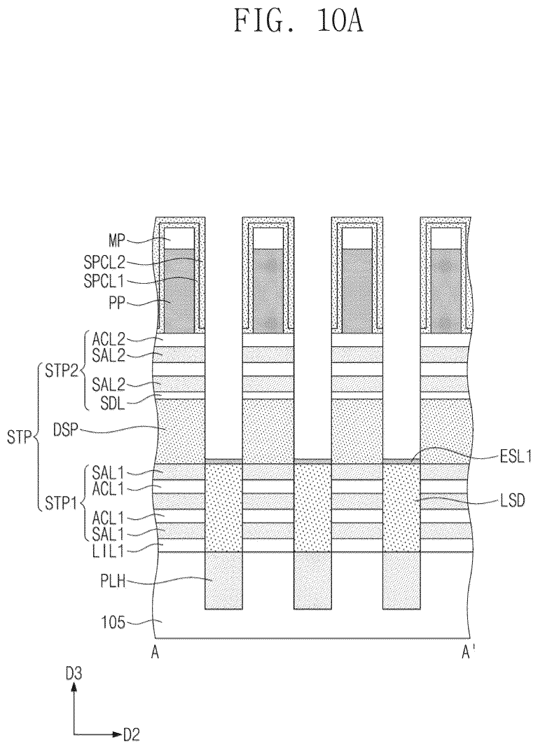

Referring to FIGS. 9A, 9B, and 9C, an etching process may be performed on the stacking pattern STP. The etching of the stacking pattern STP may include forming a mask pattern (not shown) on the sacrificial pattern PP and the hard mask pattern MP and etching the stacking pattern STP using the mask pattern (not shown) as an etch mask. As a result of the etching process, a recess RS may be formed between the sacrificial pattern PP, which are adjacent to each other. As a result of the formation of the recess RS, the stacking pattern STP may be formed to have a vertical stick shape.

At least a portion of the gapfill insulating pattern 115 may remain after the etching process of patterning the stacking pattern STP. As an example, the etching process may be performed using an etch recipe that is chosen to have a high etch rate to silicon and silicon germanium. In detail, the first and second spacer layers SPCL1 and SPCL2 covering the top surface of the gapfill insulating pattern 115 may be removed, and an upper portion of the gapfill insulating pattern 115 may also be etched. Thus, the gapfill insulating pattern 115 may have a top surface 115a, which is recessed toward the semiconductor substrate 105, between the upper source/drain patterns. The gapfill insulating pattern 115 may cover the device isolation layer 107, and thus, the device isolation layer 107 may not be etched in the etching process.

In an embodiment where the separation layer DSL includes silicon germanium (SiGe), the dummy channel pattern DSP may be formed by replacing the separation layer DSL with a silicon-based insulating material, after the formation of the recess RS. For example, the separation layer DSL exposed by the recess RS may be selectively removed, and then, a region, which is formed by the removal of the separation layer DSL, may be filled with a silicon-based insulating material (e.g., silicon nitride).

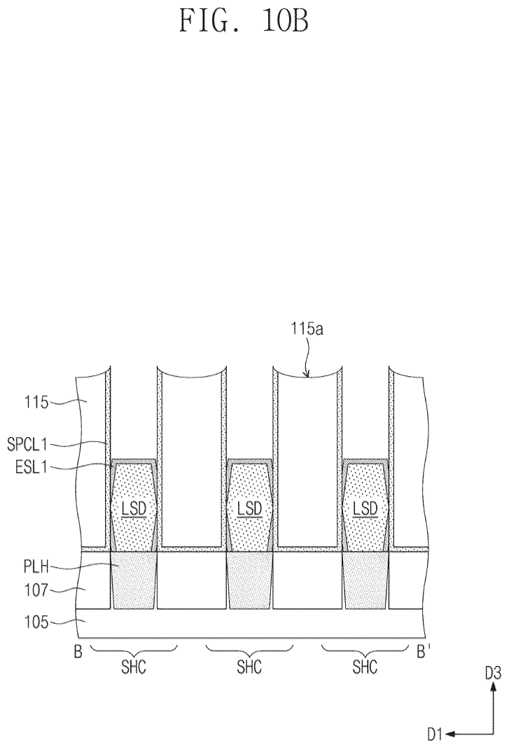

Referring to FIGS. 10A and 10B, sacrificial contact patterns PLH may be formed in the semiconductor substrate 105 exposed by the recess RS. The sacrificial contact patterns PLH may be arranged in the second direction D2. The sacrificial contact patterns PLH may be formed of or include a material (e.g., silicon-germanium (SiGe)) having an etch selectivity with respect to the semiconductor substrate 105. The sacrificial contact patterns PLH may be formed by an epitaxial growth process. The sacrificial contact pattern PLH may be formed in the recess RS.

The lower source/drain pattern LSD may be formed in the recess RS and on the sacrificial contact pattern PLH. In detail, the lower source/drain pattern LSD may be formed by a first SEG process using a side surface of the lower stacking pattern STP1, which is exposed through the recess RS, as a seed layer. The lower source/drain pattern LSD may be formed using the first active layers ACL1, which are exposed by the recess RS, as a seed layer. As an example, the first SEG process may include a chemical vapor deposition (CVD) process or a molecular beam epitaxy (MBE) process.

As an example, impurities may be injected into the lower source/drain pattern LSD in an in-situ manner during the first SEG process. As another example, impurities may be injected into the lower source/drain pattern LSD, after the formation of the lower source/drain pattern LSD. The lower source/drain pattern LSD may be doped to have a first conductivity type (e.g., an n-type). The lower source/drain pattern LSD may be formed to fully fill or be in a space between the first active layers ACL1 adjacent to each other in the second direction D2.

According to an embodiment of the inventive concept, the gapfill insulating pattern 115 may be disposed between the lower source/drain pattern LSD, which are horizontally adjacent to each other, and may prevent or suppress/inhibit the lower source/drain pattern LSD from being excessively grown in a horizontal direction. For example, the lower source/drain patterns LSD may be grown until it is in contact with the first spacer SPC1, and even when the lower source/drain patterns LSD are grown for a long enough period of time, the lower source/drain patterns LSD, which are adjacent to each other in the first direction D1, may be horizontally spaced apart from each other. In other words, the gapfill insulating pattern 115 may control a horizontal growth of the lower source/drain patterns LSD facing each other in the first direction D1.

In addition, the gapfill insulating pattern 115 may prevent or inhibit a parasitic epitaxial pattern from being formed in the device isolation layer 107. In the case where the gapfill insulating pattern 115 is not disposed, a portion of the device isolation layer 107 may be etched during the process of deeply forming the recess RS of FIG. 9B, and in this case, the parasitic epitaxial pattern may be formed in the device isolation layer 107 through the etched portion. However, according to an embodiment of the inventive concept, the gapfill insulating pattern 115, which has a sufficiently large vertical height, may be formed on the device isolation layer 107, and in this case, since the device isolation layer 107 is not exposed in the process of forming the recess RS of FIG. 9B, it may be possible to prevent or inhibit the formation of the parasitic epitaxial pattern.

The first spacer layer SPCL1 may be provided to enclose bottom and side surfaces of the gapfill insulating pattern 115. That is, the first spacer layer SPCL1 may be interposed between the gapfill insulating pattern 115 and the lower source/drain pattern LSD to prevent the lower source/drain pattern LSD from being oxidized in a process of growing the lower source/drain pattern LSD. Thereafter, the first etch stop layer ESL1 may cover the lower source/drain pattern LSD with a uniform thickness.

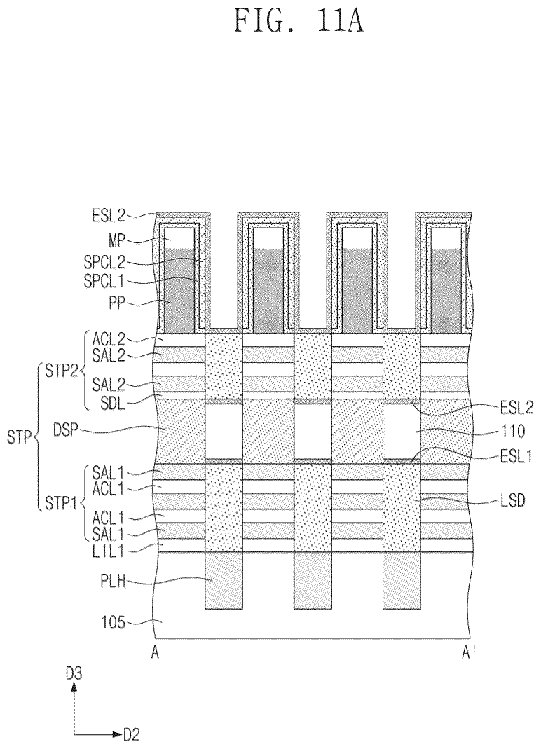

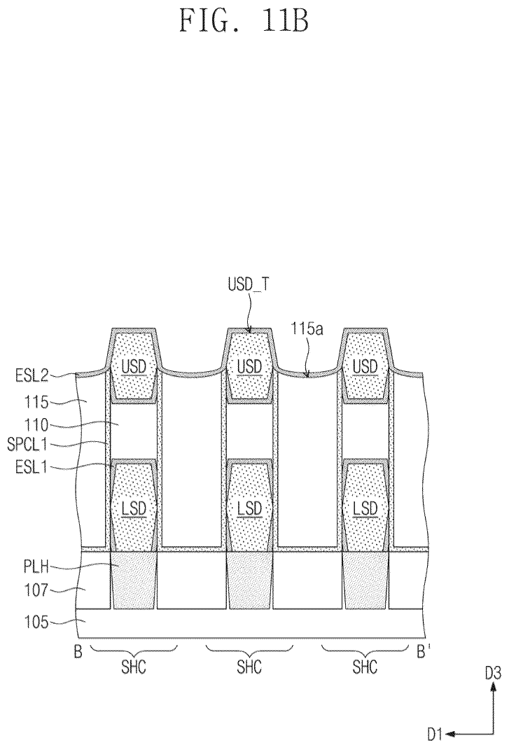

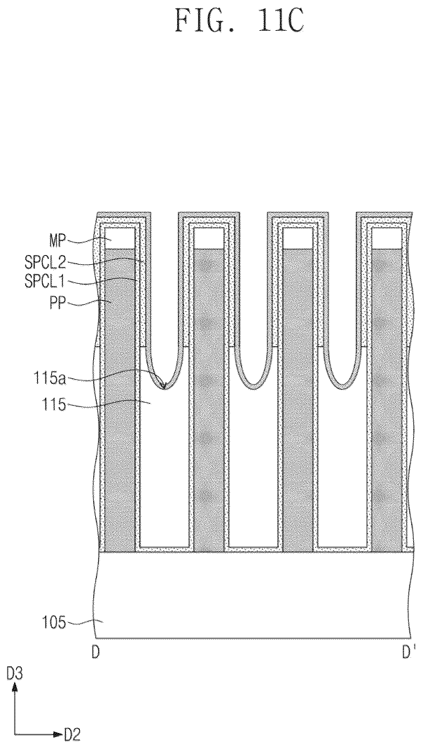

Referring to FIGS. 11A, 11B, and 11C, the first interlayer insulating layer 110 may be formed on the first etch stop layer ESL1. The first interlayer insulating layer 110 may cover or overlap at least a portion of the lower source/drain pattern LSD in the third direction D3.

In the recess RS, the first interlayer insulating layer 110 may cover or overlap at least a portion of the side surface of the upper stacking pattern STP2 in the second direction D2. Next, an upper portion of the first interlayer insulating layer 110 may be removed to expose the side surface of the upper stacking pattern STP2 in the recess RS again.

The upper source/drain pattern USD may be formed on the exposed side surface of the upper stacking pattern STP2. In detail, the upper source drain pattern USD may be formed by a second SEG process, in which the side surface of the upper stacking pattern STP2 exposed by the recess RS is used as a seed layer. The upper source/drain pattern USD may be grown using the second active layers ACL2, which are exposed through the recess RS, as a seed layer. The upper source/drain pattern USD may be doped to have the second conductivity type (e.g., p-type), which is different from the first conductivity type. The second SEG process may be performed for a long enough period of time such that the upper source/drain pattern USD is grown to sufficiently fill a space between the second active layers ACL2, which are adjacent to each other in the second direction D2.

As described above, the gapfill insulating pattern 115 may be disposed between the upper source/drain pattern USD, which are horizontally adjacent to each other, and may prevent or inhibit the upper source/drain pattern USD from being excessively grown in a horizontal direction. For example, the upper source/drain patterns USD may be grown until it is in contact with the side surface of the first spacer layer SPCL1. The upper source/drain patterns USD may be grown using the exposed second active layers ACL2 as a seed layer, and the uppermost portion USD_T of the upper source/drain patterns USD may be located at a level relative to the rear surface 100b of the substrate 100 higher than the recessed top surface 115a of the gapfill insulating pattern 115. Next, the second etch stop layer ESL2 may be conformally formed on the upper source/drain pattern USD. The second etch stop layer ESL2 may cover or overlap at least a portion of the recessed top surface 115a of the gapfill insulating pattern 115 in the third direction D3 and with a uniform thickness in the third direction D3.

Referring to FIGS. 12A to 12D, the first active layers ACL1 of FIG. 11A, which are interposed between a pair of the lower source/drain patterns LSD, may constitute the lower channel pattern LCH. For example, the first and second semiconductor patterns SP1 and SP2 of the lower channel pattern LCH may be formed from the first active layers ACL1 of FIG. 11A.

The second active layers ACL2 of FIG. 11A, which are interposed between a pair of the upper source/drain patterns USD, may constitute the upper channel pattern UCH. For example, the third and fourth semiconductor patterns SP3 and SP4 of the upper channel pattern UCH may be formed from the second active layers ACL2 of FIG. 11A.

The second interlayer insulating layer 120 may be formed on the second etch stop layer ESL2 to fill at least a portion of the recess RS. In an embodiment, the second interlayer insulating layer 120 may include a silicon oxide layer.

The second interlayer insulating layer 120 may be planarized to expose the top surface of the sacrificial pattern PP of FIG. 11A. The planarization of the second interlayer insulating layer 120 may be performed using an etch-back process or a chemical mechanical polishing (CMP) process. During the planarization process, the hard mask pattern MP on the sacrificial pattern PP of FIG. 11A may be fully removed. Upper portions of the first and second spacer layers SPCL1 and SPCL2, which are at higher levels in the third direction D3 than the level of the sacrificial pattern PP of FIG. 11A in the third direction D3 relative to the rear surface 100b of the substrate 100, may be removed to form the first and second spacers SPC1 and SPC2, respectively. The first and second spacers SPC1 and SPC2 may cover the side surface of the sacrificial pattern PP of FIG. 11A and may cover the top surface of the fourth semiconductor pattern SP4.

The exposed sacrificial pattern PP of FIG. 11A may be selectively removed. The removal of the sacrificial pattern PP may include a wet etching process using etching solution capable of selectively etching polysilicon. Since the sacrificial pattern PP is removed, the first and second sacrificial layers SAL1 and SAL2 of FIG. 11A may be exposed.

An etching process, which is chosen to selectively etch the first and second sacrificial layers SAL1 and SAL2 of FIG. 11A, may be performed to leave the first to fourth semiconductor patterns SP1 to SP4 and the dummy channel pattern DSP and to remove only the first and second sacrificial layers SAL1 and SAL2 of FIG. 11A. The etching process may be chosen to have a high etch rate to silicon germanium. For example, the etching process may be chosen to have a high etch rate to a silicon germanium layer whose germanium concentration is higher than 10 at %.

The gate insulating layer GI may be conformally formed in spaces, which are formed by removing the sacrificial pattern PP of FIG. 11A and the first and second sacrificial layers SAL1 and SAL2 of FIG. 11A. The gate electrode GE may be formed on the gate insulating layer GI. The formation of the gate electrode GE may include forming the first to fifth inner electrodes PO1 to PO5 between the first to fourth semiconductor patterns SP1 to SP4 and forming the outer electrode PO6 in a region, which is formed by removing the sacrificial pattern PP.

The cutting pattern CT may be additionally formed in the region formed by removing the sacrificial pattern PP, before or after the formation of the gate electrode GE. The cutting pattern CT may penetrate or extend into the gate electrode GE and may be extended into the device isolation layer 107.

The gate electrode GE may be vertically recessed to have a reduced height. The gate capping pattern GP may be formed on the recessed gate electrode GE and the cutting pattern CT. A planarization process may be performed on the gate capping pattern GP such that a top surface of the gate capping pattern GP is coplanar with the top surface of the second interlayer insulating layer 120.

The vertical vias VT and the penetration spacers TS may be formed to penetrate or extend into the second interlayer insulating layer 120, the gapfill insulating pattern 115, and the device isolation layer 107. The formation of the vertical vias VT and the penetration spacers TS may include forming a mask pattern, forming a penetration hole to penetrate or extend into the second interlayer insulating layer 120, the gapfill insulating pattern 115, and the device isolation layer 107, using the mask pattern as an etch mask, conformally depositing an insulating material on an inner surface of the penetration hole, and filling or depositing a metallic material in the penetration hole conformally covered with the insulating material. The metallic material may include at least one of copper (Cu), aluminum (Al), ruthenium (Ru), cobalt (Co), tungsten (W), or molybdenum (Mo).

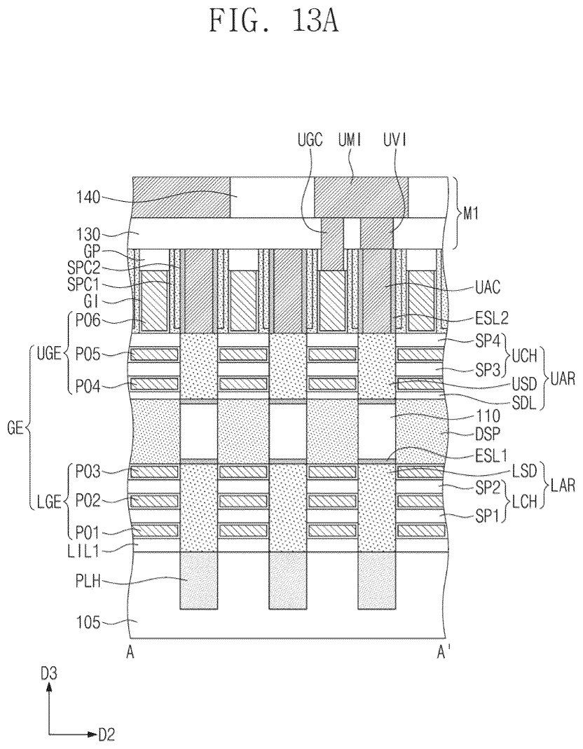

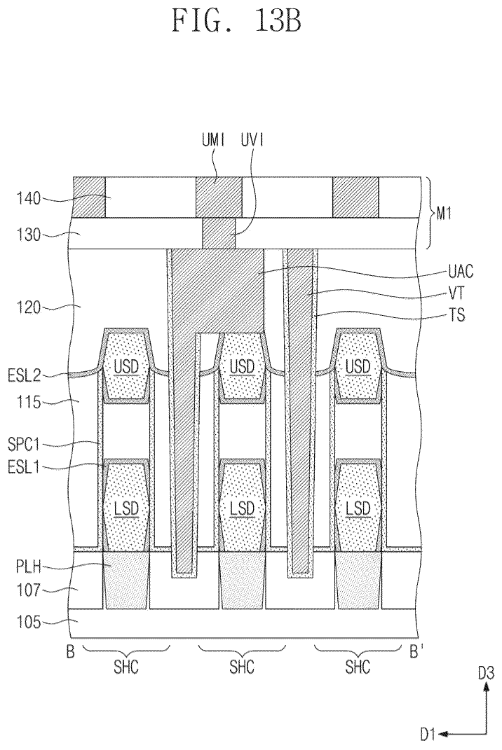

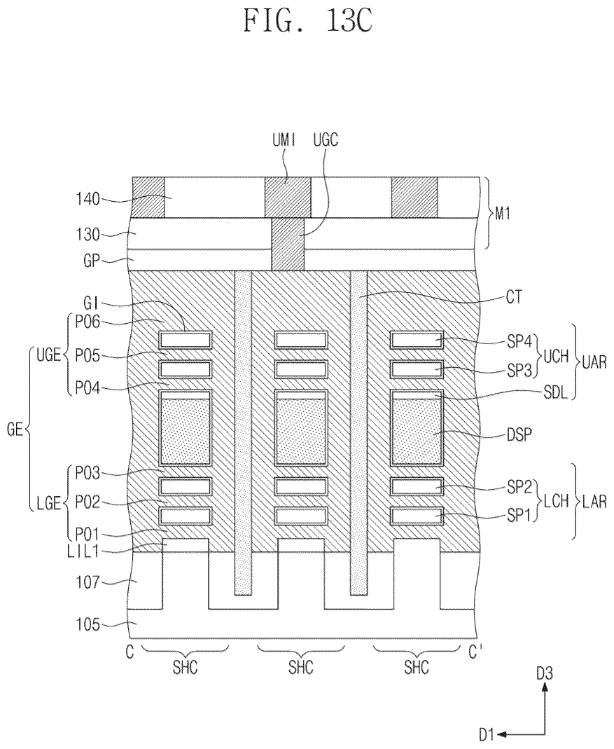

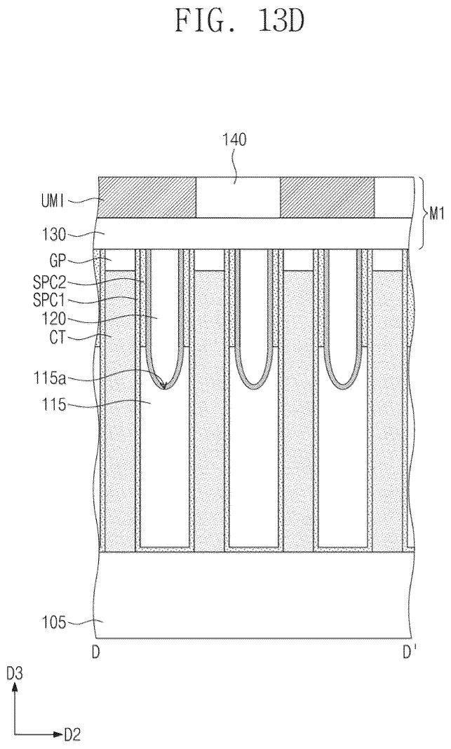

Referring to FIGS. 13A to 13D, the third interlayer insulating layer 130 may be formed on the second interlayer insulating layer 120 and the gate capping pattern GP. The upper active contacts UAC may be formed to penetrate or extend into the third interlayer insulating layer 130 and may be coupled to the upper source/drain patterns USD, respectively. The upper active contact UAC may be extended in the first direction D1 and may be in contact with an upper portion of the vertical via VT. For this, a portion of the penetration spacer TS may be removed. The upper gate contact UGC may be formed to penetrate or extend into the third interlayer insulating layer 130 and the gate capping pattern GP and to be coupled to the gate electrode GE.

A fourth interlayer insulating layer 140 may be formed to cover or overlap the third interlayer insulating layer 130 in the third direction D3. The first metal layer M1, which includes the upper interconnection lines UMI and the upper vias UVI, may be formed in the third and fourth interlayer insulating layers 130 and 140. For example, the upper vias UVI may be formed in the third interlayer insulating layer 130 to electrically connect the first metal layer M1 to the gate contacts GC and the upper active contacts UAC, and the upper interconnection lines UMI may be formed in the fourth interlayer insulating layer 140.

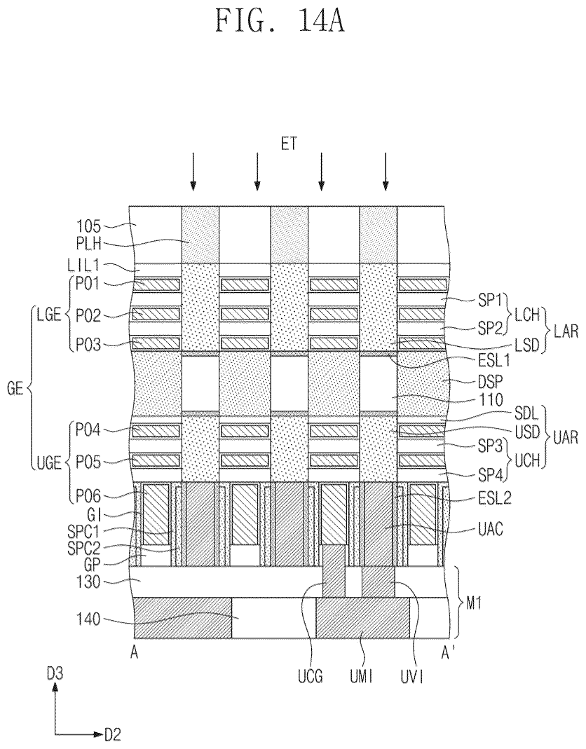

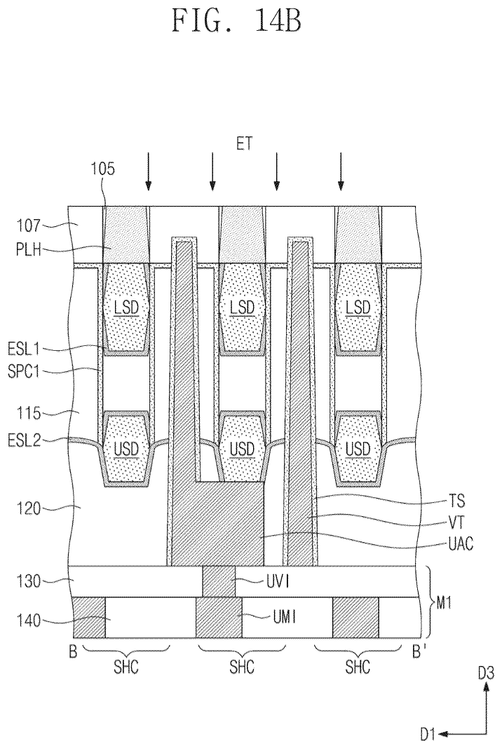

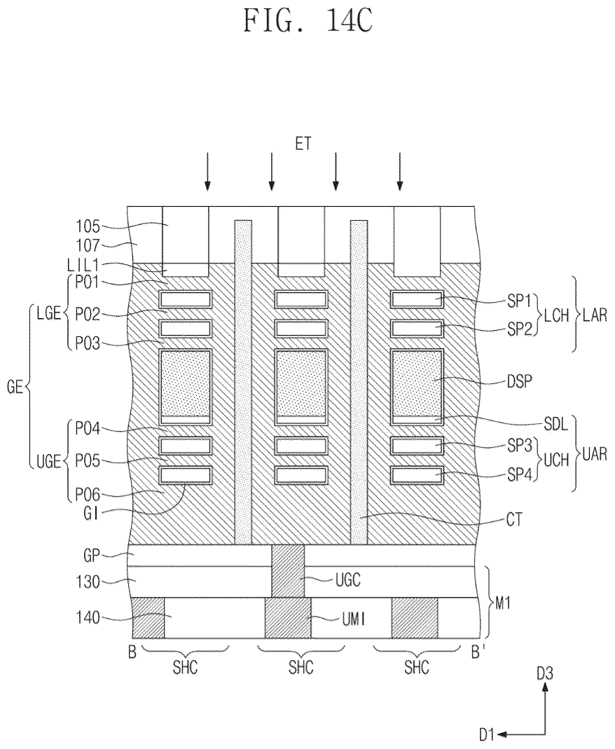

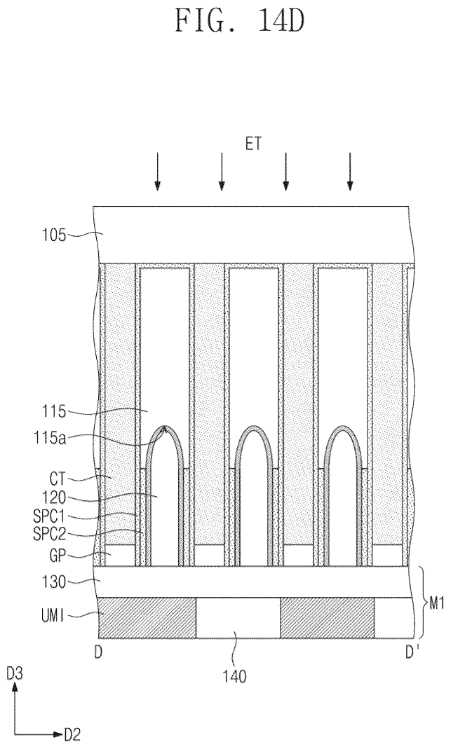

Referring to FIGS. 14A to 14D, the semiconductor substrate 105 may be inverted such that a rear surface of the semiconductor substrate 105 is exposed to the outside. An etching process may be performed on the rear surface of the semiconductor substrate 105 to reduce a height of the semiconductor substrate 105. A planarization process may be performed on the rear surface of the semiconductor substrate 105 to expose top surfaces of the sacrificial contact patterns PLH.

Referring back to FIGS. 4A to 4D, the sacrificial contact pattern PLH may be replaced with the lower active contact LAC. In detail, the sacrificial contact pattern PLH may be selectively removed. An etching process may be further performed on a region, which is formed by removing the sacrificial contact pattern PLH, to expose the lower source/drain pattern LSD. The lower active contact LAC may be formed to be coupled to the exposed lower source/drain pattern LSD. The lower active contact LAC may be formed in a self-aligned manner using the sacrificial contact pattern PLH.

In an embodiment, the semiconductor substrate 105 may be removed, and the substrate 100 including a silicon-based insulating material may be formed below the lower source/drain pattern LSD and the gate electrode GE. In an embodiment, the substrate 100 may be an insulating substrate that is formed of or includes silicon oxide and/or silicon nitride. In another embodiment, the semiconductor substrate 105 may not be removed.

The device isolation layer 107 may be partially etched to expose the bottom surface of the vertical via VT. Thereafter, a conductive pattern may be formed to horizontally connect the lower active contact LAC to the vertical via VT. The lower active contact LAC may be connected to a bottom end of the vertical via VT through the conductive pattern. For this, a portion of the penetration spacer TS may be removed.

Hereinafter, the first lower interlayer insulating layer 210 may be disposed below the device isolation layer 107 and the substrate 100. The back-side metal layer BSM may be formed in the first lower interlayer insulating layer 210. The back-side metal layer BSM may include the lower interconnection lines LMI. In addition, the lower vias LVI may be formed to electrically connect the back-side metal layer BSM to the lower active contact LAC and the lower gate contact LGC. Additional back-side metal layers may be formed on the back-side metal layer BSM. In an embodiment, the back-side metal layers may include a power delivery network.

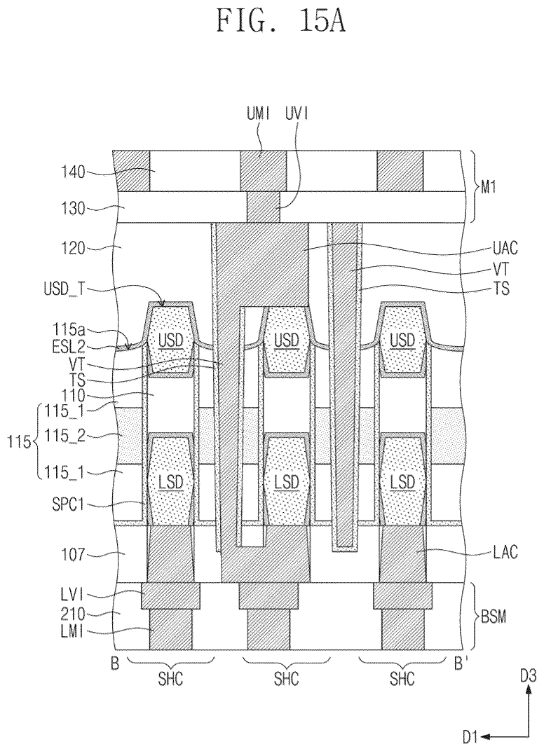

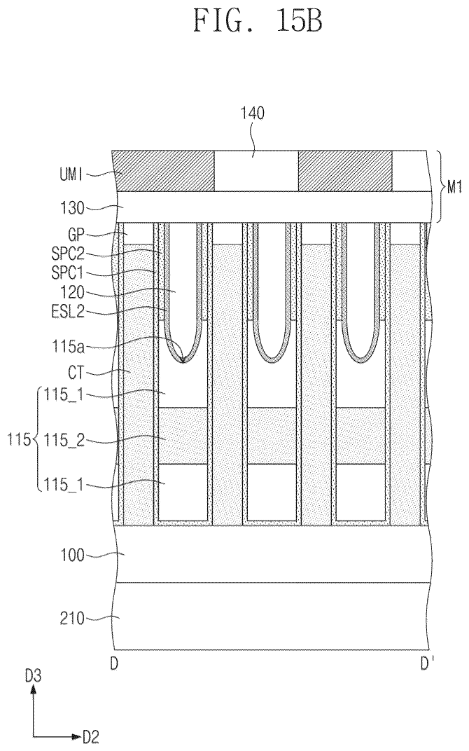

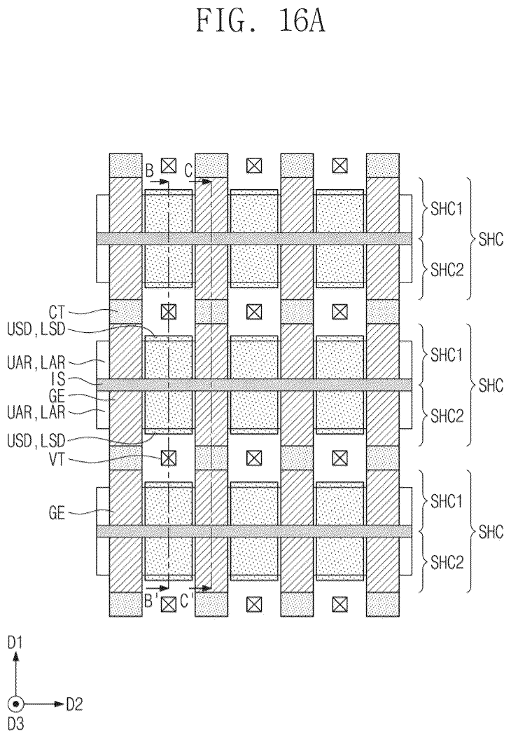

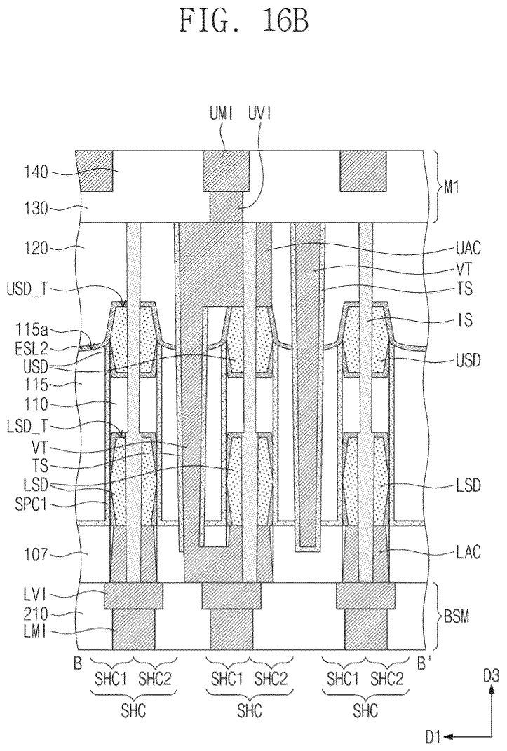

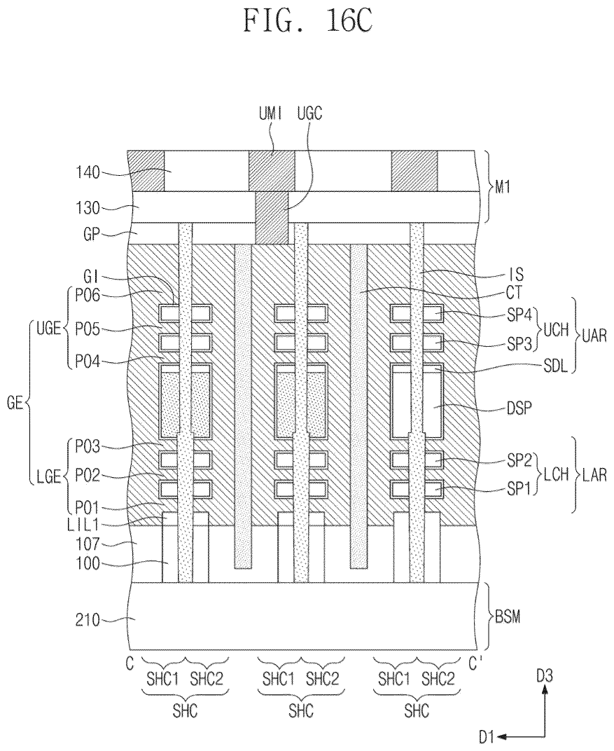

Hereinafter, several embodiments of the inventive concept will be described in more detail with reference to FIGS. 15A to 16C. In the following description, an element previously described with reference to FIG. 3 and FIGS. 4A to 4D may be identified by the same reference number without repeating an overlapping description thereof.

FIGS. 15A and 15B are sectional views illustrating a semiconductor device according to an embodiment of the inventive concept. FIG. 15A illustrates a section corresponding to FIG. 4B, and FIG. 15B illustrates a section corresponding to FIG. 4D.

Referring to FIGS. 15A and 15B, the gapfill insulating pattern 115 may include a first gapfill insulating pattern 115_1 and a second gapfill insulating pattern 115_2. In an embodiment, the gapfill insulating pattern 115 may include at least two first gapfill insulating patterns 115_1, which are vertically spaced apart from each other, and second gapfill insulating patterns 115_2, which are disposed between the first gapfill insulating patterns 115_1 in the third direction D3. Each of the first and second gapfill insulating patterns 115_1 and 115_2 may include a silicon-based insulating material (e.g., silicon oxide and/or silicon nitride).

A density of the second the gapfill insulating pattern 115_2 may be higher or greater than a density of the first gapfill insulating pattern 115_1. For example, a densification process may be repeatedly performed during the process of forming the second gapfill insulating pattern 115_2, and in this case, the second gapfill insulating pattern 115_2 may have a high density and a good etch-resistant property, compared with the first gapfill insulating pattern 115_1. By adjusting thicknesses of the first and second gapfill insulating patterns 115_1 and 115_2, which have different densities from each other, it may be possible to control an etching amount of the gapfill insulating pattern 115 in the process of forming the recess.

FIG. 16A is a plan view illustrating a semiconductor device according to an embodiment of the inventive concept, FIG. 16B is a sectional view taken along a line A-A′ of FIG. 16A, and FIG. 16C is a sectional view taken along a line C-C′ of FIG. 16A.

Referring to FIGS. 16A to 16C, the single height cell SHC may include a first single height cell SHC1 and a second single height cell SHC2, which are spaced apart from each other in the first direction D1. An insulating structure IS may be provided between the first and second single height cells SHC1 and SHC2 in the first direction D1. For example, the insulating structure IS may be a bar-shaped or line-shaped pattern that is extended in the second direction D2.

The insulating structure IS may be disposed between the gate electrodes GE, which are adjacent to each other in the first direction D1. The insulating structure IS may separate adjacent ones of the gate electrodes GE from each other. The adjacent ones of the gate electrodes GE may be spaced apart from each other in the first direction D1 by the insulating structure IS. The insulating structure IS may include an insulating material. For example, the insulating structure IS may be formed of or include at least one of SiON, SiCN, SiCON, or SiN.

A level of the top surface of the insulating structure IS in the third direction D3 relative to the rear surface 100b of the substrate 100 may be equal to or higher than a level of the top surfaces of the gate electrodes GE in the third direction D3 relative to the rear surface 100b of the substrate 100. A level of the bottom surface of the insulating structure IS in the third direction D3 relative to the rear surface 100b of the substrate 100 may be equal to or lower than a level of the bottom surfaces of the gate electrodes GE in the third direction D3 relative to the rear surface 100b of the substrate 100. The insulating structure IS may penetrate or extend into the gate electrode GE in the vertical direction D3.

The insulating structure IS may extend in the vertical direction D3 to span the lower and upper active regions LAR and UAR. The insulating structure IS may be extended from the lower active contact LAC to the upper active contact UAC in the vertical direction D3.

The insulating structure IS may be provided to pass through or extend into a region between the upper source/drain patterns USD. The insulating structure IS may be provided to pass through or extend into a region between the lower source/drain patterns LSD. A side surface of the insulating structure IS may be in direct contact with the upper source/drain pattern USD and the lower source/drain pattern LSD.

A level of the top surface of the insulating structure IS in the third direction D3 relative to the rear surface 100b of the substrate 100 may be equal to or higher than a level of the top surface of the upper active contact UAC in the third direction D3 relative to the rear surface 100b of the substrate 100. The insulating structure IS may separate the adjacent ones of the upper active contacts UAC from each other. A level of the bottom surface of the insulating structure IS in the third direction D3 relative to the rear surface 100b of the substrate 100 may be equal to or lower than a level of the bottom surface of the lower active contact LAC in the third direction D3 relative to the rear surface 100b of the substrate 100.

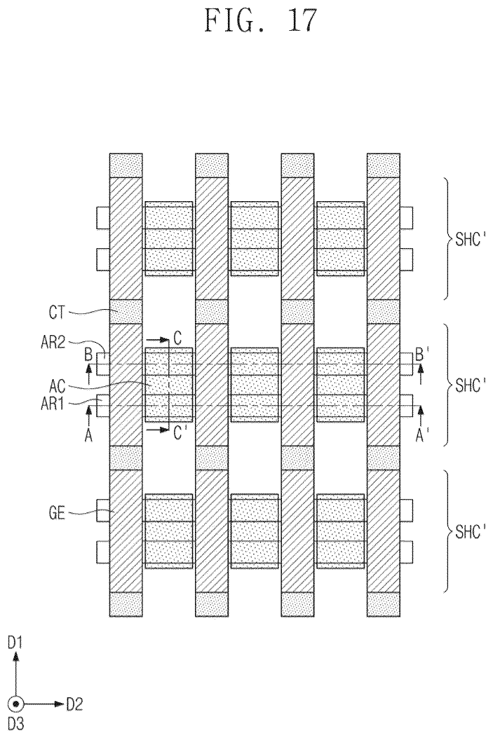

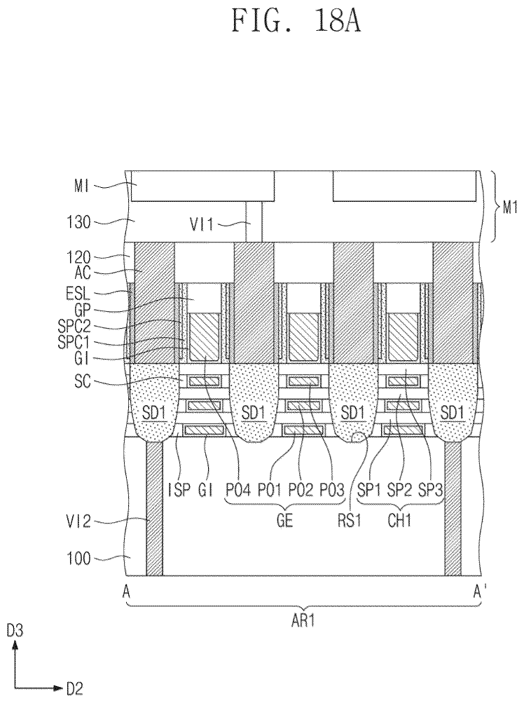

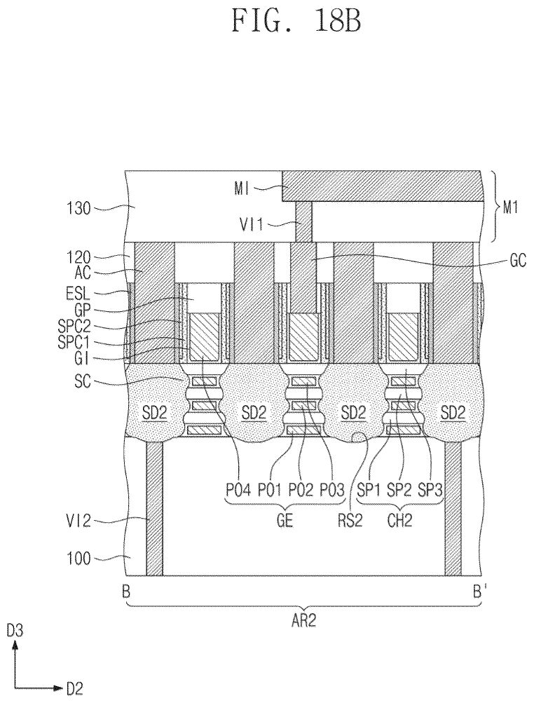

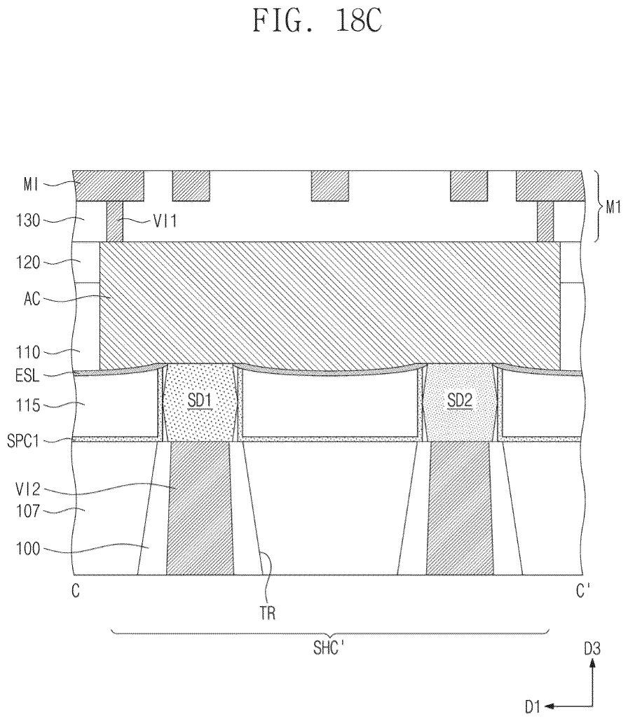

FIG. 17 and FIGS. 18A to 18C are plan and sectional views illustrating a semiconductor device according to an embodiment of the inventive concept. FIG. 17 is a plan view illustrating a semiconductor device according to an embodiment of the inventive concept, and FIGS. 18A to 18C are sectional views taken along lines A-A′, B-B′, and C-C′ of FIG. 17.

Referring to FIG. 17 and FIGS. 18A to 18C, the single height cell SHC′ may be provided on the substrate 100. The single height cell SHC′ may be a logic cell including the three-dimensional device previously described with reference to FIG. 1.

The substrate 100 may include the first active region AR1 and the second active region AR2. Each of the first and second active regions AR1 and AR2 may be extended in the second direction D2. In an embodiment, the first active region AR1 may be an NMOSFET region, and the second active region AR2 may be a PMOSFET region.

The first and second active regions AR1 and AR2 may be defined by the trench TR, which is formed in an upper portion of the substrate 100. The first active region AR1 may be provided on the first active region AR1, and the second active region AR2 may be provided on the second active region AR2. The first and second active patterns AP1 and AP2 may be extended in the second direction D2. Each of the first and second active patterns AP1 and AP2 may be a vertically protruding or extending portion of the substrate 100.

The device isolation layer 107 may be provided on the substrate 100. A device isolation layer ST may fill at least a portion of the trench TR. The device isolation layer 107 may include a silicon oxide layer or a silicon nitride layer. The device isolation layer 107 may not cover or overlap the first and second channel patterns CH1 and CH2 in the third direction D3, which will be described below.

The first channel pattern CH1 may be provided on the first active region AR1. The second channel pattern CH2 may be provided on the second active region AR2. Each of the first and second channel patterns CH1 and CH2 may include the first semiconductor pattern SP1, the second semiconductor pattern SP2, and the third semiconductor pattern SP3, which are sequentially stacked. The first to third semiconductor patterns SP1, SP2, and SP3 may be spaced apart from each other in a vertical direction (i.e., the third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon, in particular, single crystalline silicon. In an embodiment, the first to third semiconductor patterns SP1, SP2, and SP3 may be nanosheets that are stacked.

A plurality of first source/drain patterns SD1 may be provided on the first active region AR1. A plurality of first recesses RS1 may be formed in an upper portion of the first active region AR1. The first source/drain patterns SD1 may be provided in the first recesses RS1, respectively. The first source/drain patterns SD1 may be impurity regions of a first conductivity type (e.g., n-type). The first channel pattern CH1 may be interposed between a pair of the first source/drain patterns SD1. That is, each pair of the first source/drain patterns SD1 may be connected to each other by the first to third semiconductor patterns SP1, SP2, and SP3.

A plurality of second source/drain patterns SD2 may be provided on the second active region AR2. A plurality of second recesses RS2 may be formed in an upper portion of the second active region AR2. The second source/drain patterns SD2 may be provided in the second recesses RS2, respectively. The second source/drain patterns SD2 may be impurity regions of a second conductivity type (e.g., p-type). The second channel pattern CH2 may be interposed between a pair of the second source/drain patterns SD2. That is, each pair of the second source/drain patterns SD2 may be connected to each other by the first to third semiconductor patterns SP1, SP2, and SP3.

The first and second source/drain patterns SD1 and SD2 may be epitaxial patterns that are formed by a selective epitaxial growth (SEG) process. In an embodiment, a level of a top surface of each of the first and second source/drain patterns SD1 and SD2 in the third direction D3 relative to the rear surface 100b of the substrate 100 may be higher than a level of a top surface of the third semiconductor pattern SP3 in the third direction D3 relative to the rear surface 100b of the substrate 100. In another embodiment, at least one of the first and second source/drain patterns SD1 and SD2 may have a top surface that is located at substantially the same level as the top surface of the third semiconductor pattern SP3 in the third direction D3 relative to the rear surface 100b of the substrate 100.

In an embodiment, the first source/drain patterns SD1 may be formed of or include the same semiconductor element (e.g., Si) as the substrate 100. The second source/drain patterns SD2 may include a semiconductor material (e.g., SiGe) whose lattice constant is greater than that of the substrate 100. In this case, the pair of the second source/drain patterns SD2 may exert a compressive stress on the second channel pattern CH2 therebetween.

In an embodiment, the second source/drain pattern SD2 may have an uneven or embossing side surface. That is, the side surface of the second source/drain pattern SD2 may have a wavy profile. The side surface of the second source/drain pattern SD2 may protrude or extend toward first to third portions PO1, PO2, and PO3 of the gate electrode GE to be described below.

The gate electrodes GE may be provided on the first and second channel patterns CH1 and CH2. Each of the gate electrodes GE may be extended in the first direction D1 to cross the first and second channel patterns CH1 and CH2. Each of the gate electrodes GE may be vertically overlapped (e.g., overlapped in the third direction D3) by the first and second channel patterns CH1 and CH2. The gate electrodes GE may be arranged with a first pitch in the second direction D2.

The gate electrode GE may include a first portion PO1 interposed between the active pattern AP1 or AP2 and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

The gate capping pattern GP may be provided on the gate electrode GE. The gate capping pattern GP may be extended along the gate electrode GE or in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, or SiN.

A pair of the first and second spacers SPC1 and SPC2 may be respectively disposed on opposite side surfaces of the fourth portion PO4 of the gate electrode GE. The first and second spacers SPC1 and SPC2 may be extended along the gate electrode GE and in the first direction D1. A level of the top surfaces of the first and second spacers SPC1 and SPC2 in the third direction D3 relative to the rear surface 100b of the substrate 100 may be higher than a level of the top surface of the gate electrode GE in the third direction D3 relative to the rear surface 100b of the substrate 100. The top surfaces of the first and second spacers SPC1 and SPC2 may be coplanar with the top surface of the gate capping pattern GP. In an embodiment, the first and second spacers SPC1 and SPC2 may be formed of or include at least one of SiCN, SiCON, or SiN and at least one of the first and second spacers SPC1 and SPC2 may further include a low-k dielectric material. The second spacer SPC2 may be used as an etch stop layer in a process of forming active contacts AC, which will be described below.

The third interlayer insulating layer 130 may be disposed on the second interlayer insulating layer 120. The first metal layer M1 may be provided in the third interlayer insulating layer 130. For example, the first metal layer M1 may include first interconnection lines MI and a first via VI1. The first vias VI1 may be respectively provided below the first interconnection lines MI of the first metal layer M1. The active contact AC and the first interconnection lines MI may be electrically connected to each other through the first via VI1. The active contact AC may be connected to the first and second source/drain patterns SD1 and SD2. The gate contact GC and the first interconnection lines MI may be electrically connected to each other through the first via VI1.

A second via VI2 may be disposed to penetrate or extend into a portion of the substrate 100. The second via VI2 may be connected to each of the first and second source/drain patterns SD1 and SD2 and may be disposed below the first and second source/drain patterns SD1 and SD2.

The second vias VI2 may connect power interconnection lines (not shown), which are provided on a rear surface of the substrate 100, to the first and second source/drain patterns SD1 and SD2. Referring to FIG. 18C, the device isolation layer 107 may be provided on the substrate 100. The device isolation layer 107 may fill at least a portion of the trench TR. The device isolation layer 107 may include a silicon oxide layer or a silicon nitride layer.

The gapfill insulating pattern 115 may be disposed on the substrate 100 and the device isolation layer 107. The gapfill insulating pattern 115 may cover or overlap the substrate 100 and the top surface of the device isolation layer 107 in the third direction D3. The gapfill insulating pattern 115 may be disposed between the first and second source/drain patterns SD1 and SD2, which are adjacent to each other, and may face the side surfaces of the first and second source/drain patterns SD1 and SD2.

The gapfill insulating pattern 115 may suppress an excessive horizontal growth of the first and second source/drain patterns SD1 and SD2. For example, the first and second source/drain patterns SD1 and SD2 may be grown until they are in contact with the gapfill insulating pattern 115 or the first spacer SPC1. Thus, even when the first and second source/drain patterns SD1 and SD2 are grown for a long enough period of time, the first and second source/drain patterns SD1 and SD2 may be horizontally spaced apart from each other. That is, the gapfill insulating pattern 115 may control a horizontal growth of the first and second source/drain patterns SD1 and SD2 facing each other.

The first spacer layer SPC1 may be provided to enclose bottom and side surfaces of the gapfill insulating pattern 115. That is, the first spacer layer SPC1 may be interposed between the gapfill insulating pattern 115 and the lower source/drain pattern LSD to prevent or inhibit the first and second source/drain patterns SD1 and SD2 from being partially oxidized in the growth process of the first and second source/drain patterns SD1 and SD2.

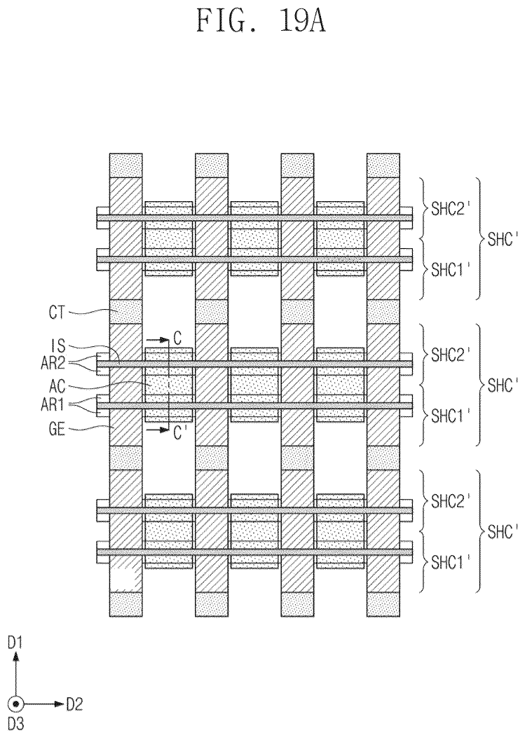

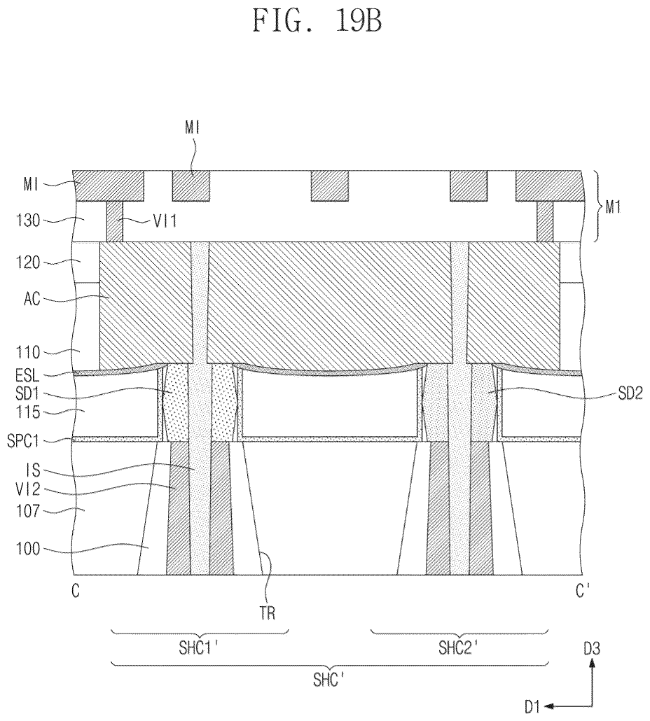

FIGS. 19A and 19B are plan and sectional views illustrating a semiconductor device according to an embodiment of the inventive concept. FIG. 19B is a sectional view taken along a line A-A′ of FIG. 19A. In the following description, an element previously described with reference to FIG. 17 and FIGS. 18A to 18C may be identified by the same reference number without repeating an overlapping description thereof.

Referring to FIGS. 19A and 19B, the single height cell SHC′ may include a first single height cell SHC1′ and a second single height cell SHC2′, which are spaced apart from each other in the first direction D1. Each of the first and second single height cells SHC1′ and SHC2′ may include the insulating structure IS. In an embodiment, the first single height cells SHC1′ may include the first active regions AR1, which are respectively disposed at both sides of the insulating structure IS, and the second single height cells SHC2′ may include the second active regions AR2, which are respectively disposed at both sides of the insulating structure IS. That is, in the first single height cell SHC1′, the first source/drain patterns SD1 may be spaced apart from each other in the first direction D1 with the insulating structure IS interposed therebetween, and in the second single height cell SHC2′, the second source/drain pattern SD2 may be spaced apart from each other in the first direction D1 with the insulating structure IS interposed therebetween.

In other words, the insulating structure IS may be interposed between the first source/drain patterns SD1 and between the second source/drain patterns SD2 in the first direction D1, and the side surface of the insulating structure IS may be in direct contact with the first and second source/drain patterns SD1 and SD2.

The insulating structure IS may be extended from the active contact AC to the second via VI2 in the vertical direction (e.g., the third direction D3). The insulating structure IS may separate the adjacent ones of the active contacts AC from each other. For example, the insulating structure IS may be formed of or include at least one of SiON, SiCN, SiCON, or SiN.

In a semiconductor device according to an embodiment of the inventive concept, a gapfill insulating pattern may be provided to face a side surface of a lower source/drain pattern and a side surface of an upper source/drain pattern. The gapfill insulating pattern may be disposed before the formation of the lower and upper source/drain patterns and may prevent or inhibit the lower and upper source/drain patterns from being excessively grown in a horizontal direction.

Furthermore, the gapfill insulating pattern may be disposed on a device isolation layer. The gapfill insulating pattern may serve as a buffer pattern preventing or inhibiting the device isolation layer from being etched when a recess is formed between stacking patterns to form the lower and upper source/drain patterns. Accordingly, it may be possible to prevent or inhibit a parasitic epitaxial pattern from being formed in the device isolation layer. In addition, the reliability and electrical characteristics of the semiconductor device may be improved.

While example embodiments of the inventive concept have been particularly shown and described, it will be understood by one of ordinary skill in the art that variations in form and detail may be made therein without departing from the scope of the attached claims.

What is claimed is:

1. A semiconductor device, comprising:
a lower active region on a substrate, the lower active region comprising a lower channel pattern and a lower source/drain pattern electrically connected to the lower channel pattern;
an upper active region on the lower active region, the upper active region comprising an upper channel pattern and an upper source/drain pattern electrically connected to the upper channel pattern; and
a gapfill insulating pattern,
wherein a side surface of the gapfill insulating pattern faces a side surface of the lower source/drain pattern and a side surface of the upper source/drain pattern,
wherein the gapfill insulating pattern has a recessed top surface, and
wherein a distance between the recessed top surface of the gapfill insulating pattern and a lower surface of the substrate in a first direction that is perpendicular to the lower surface of the substrate is greater than a distance between an uppermost portion of the lower source/drain pattern and the lower surface of the substrate in the first direction and is less than a distance between an uppermost portion of the upper source/drain pattern and the lower surface of the substrate in the first direction.

2. The semiconductor device of claim 1, further comprising a first spacer between the side surface of the gapfill insulating pattern and the side surface of the lower source/drain pattern in a second direction that is parallel to the lower surface of the substrate, wherein the first spacer is between a bottom surface of the gapfill insulating pattern and the substrate in the first direction.

3. The semiconductor device of claim 2, further comprising a device isolation layer that is in the substrate and contacts the first spacer.

4. The semiconductor device of claim 3, further comprising an etch stop layer on the upper source/drain pattern and the recessed top surface of the gapfill insulating pattern.

5. The semiconductor device of claim 4, further comprising an interlayer insulating layer on the etch stop layer, wherein the etch stop layer is between the interlayer insulating layer and the gapfill insulating pattern in the first direction.

6. The semiconductor device of claim 1, wherein the recessed top surface of the gapfill insulating pattern faces the substrate and overlaps at least a portion of the upper source/drain pattern in a second direction that is parallel to the lower surface of the substrate.

7. The semiconductor device of claim 1, further comprising:
a lower active contact electrically connected to the lower source/drain pattern;
an upper active contact electrically connected to the upper source/drain pattern; and
a via that electrically connects the lower active contact to the upper active contact and extends in the first direction,
wherein the via extends into the gapfill insulating pattern.

8. The semiconductor device of claim 1, wherein:
the lower source/drain pattern has a first conductivity type, and
the upper source/drain pattern has a second conductivity type different from the first conductivity type.

9. The semiconductor device of claim 1, wherein:
the gapfill insulating pattern further comprises first gapfill insulating patterns that are spaced apart from each other in the first direction, and a second gapfill insulating pattern that is between the first gapfill insulating patterns in the first direction, and
a density of the second gapfill insulating pattern is greater than a density of the first gapfill insulating patterns.

10. The semiconductor device of claim 1, further comprising a gate electrode on the lower channel pattern and the upper channel pattern,
wherein each of the lower channel pattern and the upper channel pattern comprises semiconductor patterns that are spaced apart from each other in the first direction, and
wherein the gate electrode comprises:
a lower gate electrode surrounding at least a portion of the semiconductor patterns of the lower channel pattern; and
an upper gate electrode surrounding at least a portion of the semiconductor patterns of the upper channel pattern.

11. The semiconductor device of claim 10, further comprising an insulating structure that extends into the gate electrode in the first direction, wherein a distance between a top surface of the insulating structure and the lower surface of the substrate in the first direction is greater than a distance between a top surface of the gate electrode and the lower surface of the substrate in the first direction.

12. A semiconductor device, comprising:
a lower active region on a substrate, the lower active region comprising a lower channel pattern and lower source/drain patterns electrically connected to the lower channel pattern;
an upper active region on the lower active region, the upper active region comprising an upper channel pattern and upper source/drain patterns electrically connected to the upper channel pattern;
a gate electrode on the lower channel patterns and the upper channel patterns, the gate electrode comprising a lower gate electrode on the lower channel pattern, an upper gate electrode on the upper channel pattern, and an outer electrode that is an uppermost portion of the upper gate electrode;
a gapfill insulating pattern, a side surface of the gapfill insulating pattern facing side surfaces of the lower source/drain patterns and side surfaces of the upper source/drain patterns;
a first spacer on a side surface of the outer electrode and the side surface of the gapfill insulating pattern; and
a second spacer on a side surface of the first spacer,
wherein the gapfill insulating pattern has a top surface that is recessed toward the substrate in a first direction that is perpendicular to a lower surface of the substrate, and wherein the top surface of the gapfill insulating pattern is between the upper source/drain patterns in a second direction that is parallel to the lower surface of the substrate.

13. The semiconductor device of claim 12, wherein a dielectric constant of the second spacer is less than a dielectric constant of the first spacer.

14. The semiconductor device of claim 12, further comprising an etch stop layer on the upper source/drain patterns and a side surface of the second spacer.

15. The semiconductor device of claim 14, wherein the etch stop layer is on the top surface of the gapfill insulating pattern.

16. The semiconductor device of claim 12, further comprising:
a lower active contact electrically connected to the lower source/drain patterns;
an upper active contact electrically connected to the upper source/drain patterns; and
a vertical via that electrically connects the lower active contact to the upper active contact and extends in the first direction,
wherein the vertical via extends into the gapfill insulating pattern.

17. The semiconductor device of claim 12, wherein:
the gapfill insulating pattern further comprises first gapfill insulating patterns that are spaced apart from each other in the first direction, and a second gapfill insulating pattern that is between the first gapfill insulating patterns in the first direction, and
a density of the second gapfill insulating pattern is greater than a density of the first gapfill insulating pattern.

18. The semiconductor device of claim 12, further comprising an insulating structure that extends into the gate electrode in the first direction, wherein a distance between a top surface of the insulating structure and the lower surface of the substrate in the first direction is greater than a distance between a top surface of the gate electrode and the lower surface of the substrate in the first direction.

19. A semiconductor device, comprising:
a lower active region on a substrate, the lower active region comprising a lower channel pattern and a lower source/drain pattern electrically connected to the lower channel pattern;
an upper active region on the lower active region, the upper active region comprising an upper channel pattern and an upper source/drain pattern electrically connected to the upper channel pattern;
a gate electrode on the lower channel pattern and the upper channel pattern, the gate electrode comprising a lower gate electrode on the lower channel pattern, an upper gate electrode on the upper channel pattern, and an outer electrode that is an uppermost portion of the upper gate electrode;
a gapfill insulating pattern, a side surface of the gapfill insulating pattern facing a side surface of the lower source/drain pattern and a side surface of the upper source/drain pattern;
a first interlayer insulating layer on the lower source/drain pattern;
a second interlayer insulating layer on the upper source/drain pattern;
a lower active contact electrically connected to the lower source/drain pattern;
an upper active contact electrically connected to the upper source/drain pattern;
a first spacer on a side surface of the outer electrode and the side surface of the gapfill insulating pattern; and
a second spacer on a side surface of the first spacer,
wherein the gapfill insulating pattern has a recessed top surface, and
wherein a distance between the recessed top surface of the gapfill insulating pattern and a lower surface of the substrate in a first direction that is perpendicular to a lower surface of the substrate is greater than a distance between an uppermost portion of the lower source/drain pattern and the lower surface of the substrate in the first direction and is less than a distance between an uppermost portion of the upper source/drain pattern and the lower surface of the substrate in the first direction.

20. The semiconductor device of claim 19, further comprising an insulating structure that extends into the gate electrode in the first direction, wherein a distance between a top surface of the insulating structure and the lower surface of the substrate in the first direction is greater than a distance between a top surface of the gate electrode and the lower surface of the substrate in the first direction.
